(19) United States
(12) Patent Application Publication
(10) Pub. No.: US 2024/0191056 A1
(43) Pub. Date: Jun. 13, 2024

(54) ZIRCONIA AND TITANIA FORMULATIONS AND NANOCOMPOSITES FOR NANOIMPRINT LITHOGRAPHY

(71) Applicants: PT SPE SUBCO LLC, Baltimore, MD (US); PIXELLIGENT TECHNOLOGIES LLC, Baltimore, MD (US)

(72) Inventors: Peter Christopher GUSCHL, Abingdon, MD (US); Grace E. M. MCCLINTOCK, Baltimore, MD (US); Mohammadreza AMIRMOSHIRI, Baltimore, MD (US)

(21) Appl. No.: 18/552,322

(22) PCT Filed: Mar. 28, 2022
(86) PCT No.: PCT/US2022/022120

§ 371 Date: Sep. 25, 2023

Related U.S. Application Data
(60) Provisional application No. 63/166,591, filed on Mar. 26, 2021.

(51) Int. Cl. C08K 3/22; C08F 222/10; G03F 7/00; G03F 7/004; G03F 7/028

(52) U.S. Cl. CPC C08K 3/22; C08F 222/102; G03F 7/0002; G03F 7/0047; G03F 7/028; C08K 2003/2237; C08K 2003/2244; C08K 2201/011

(57) ABSTRACT

The present disclosure provides a high-refractive index acrylic formulation comprised of sub-30 nm zirconium and/or titanium oxide nanocrystals. The formulation is solvent-containing or solvent-free, of imprintable and/or inkjet-printable viscosities, can be applied by multiple film deposition techniques and produces high-refractive index, high transparency nanocomposites for a variety of optical applications including AR/VR/MR and display applications.

### CROSS REFERENCE TO RELATED APPLICATIONS

This application claims priority of U.S. provisional application No. 63/166,591 filed Mar. 26, 2021, the contents of which are incorporated herein by reference in their entirety.

Polymeric nanocomposite formulations described herein exhibit nanoimprinting capabilities of a variety of structure geometries and aspect ratios in addition to high refractive index and high optical transmittance in the visible spectrum. The materials of the present disclosure are easily coated onto the surface of desired substrates via common solution coating processes, such as inkjet printing, spin coating, screen printing, dip, dispense, roll-to-roll, slot die, or draw bar coating for many electronic applications. The nanocomposites of the present disclosure are prepared from formulations comprising titania and/or zirconia nanocrystals and monomers or oligomers, initiators, and other additives. The nanocomposites of the present disclosure are unique in providing high refractive index and high transparency films or coatings or layers which are desirable in electronics applications, such as augmented reality, mixed reality and/or virtual reality applications where these properties are important to the performance. The thickness of coatings described herein range from tens of nanometers to micrometers, as required for specific applications.

One of the leading applications for TiO₂ and ZrO₂ nanocomposites is for use in Diffractive Optical Elements (DOE). DOEs are very small structure patterns, used in optical devices to change the phase of the light propagated through the optical structures. The application ranges and markets served by DOE are very broad. Examples of DOE include diffractive optical waveguides, beam splitters and diffractive diffusers for optical sensors, medical laser treatments and diagnostics instruments, optical distance and speed measurement systems, fiber coupling, and laser display and illumination systems. These materials must be optically clear and nano-imprintable to meet the industry needs in DOE applications and balancing these optical and mechanical properties is vital for the growing demands in high RI DOEs.

One of the leading markets where DOE is having an impact is Extended Reality (XR), which encompasses Augmented Reality (AR), Mixed Reality (MR), and Virtual Reality (VR). Balancing the optical and mechanical properties is critical in delivering the optically clear and nanoimprintable materials that this industry is demanding. TiO₂ and ZrO₂ nanocomposites for high-RI applications, such as AR/VR, where maintaining optical clarity and the necessary mechanical properties for nanoimprinting are as critical as the high-RI values themselves.

Nanoimprinting (NI) applications typically utilize film deposition methods, such as spin coating and inkjet printing, as the basis for a uniform distribution of nano-sized structures unique to the desired application. NI structures can be gratings that are vertical or slanted, rectangular, cylindrical or triangular with specific heights/widths (e.g. aspect ratios) and pitches. Other more complicated structures are common in nanoimprinting and are known as diffractive optical elements, comprising specific three-dimensional arrays of structures of varying heights and other dimensions.

In general, nanoimprinting involves a stamp and a substrate with the pre-cured film deposited upon it. The stamps could be hard or soft, but it must be transparent specifically in the UV wavelength region unique to the formulation's photoinitiator absorption. Hard stamps are traditionally made from a type of glass, and soft stamps are often made from a transparent flexible material like polydimethylsiloxane (PDMS). Conversely, the stamps could be opaque or translucent if the substrate for the film is transparent in the manner just described. The process follows such that the stamp is placed upon the pre-cured film, a pressure is applied for a certain amount of time to allow the film to flow into the stamp, UV light shines through the transparent stamp or substrate, and the stamp is separated from the cured film. Other methods can incorporate thermal cures and do not require a transparent stamp. To facilitate the release of the stamp from the film/substrate, release agents are often applied to the stamp to prevent cohesive and/or adhesive failures of the film/structures.

There are many important factors that determine whether a formulation is nanoimprintable: film viscosity prior to cure (little to no solvent), hardness, Young's modulus and shrinkage of the cured structures. The pre-cured film viscosity requires a level of flowability such that the material can be incorporated uniformly throughout the intended regions of the working stamp to give the final structures. The dimensions of the stamps and the processing time of applied pressures dictate the viscosity limitations.

Mechanical properties of the cured structures, such as hardness and Young's modulus, are important such that the structure remain intact after the imprinting process is complete. A common imprinting method is to use a soft stamp that is peeled off from the cured film. There are shear forces and strains subjected to the nanoscale structures that must be overcome. Young's modulus is a direct measure of the stiffness or resistance to strain under a given applied stress. The hardness, which is the resistance to deformation, of the structures is necessary to be sufficiently high enough such that the intended geometries and array do not become displaced or out of alignment.

Shrinkage is an important nanoimprint property that should be minimized for maintaining structural dimensions at the desired level. Shrinkage is known to occur for UV-curable films as they transition from the pre-cure to final cure state as double bonds convert and crosslinks form. Ultimately, changes between the monomer and polymer densities give rise to shrinkage. Traditionally, monomers with low functionalities (e. g. 1 or 2 acrylates) tend to have low shrinkages (e. g. less than 5%), and, conversely, monomers with high functionalities (e. g. crosslinkers with 3 or more acrylates) have shown high degrees of shrinkage of 10% or more.

NI formulations can be solvent-containing or solvent-free. The main determinants for which type of formulation to use are the desired film thicknesses and processing steps. Solvent-containing formulations are typically of low viscosity (less than or equal to 5 cP) and can have low solids content (less than or equal to 30 wt %) for the purposes of creating thin films (less than or equal to 5 micron). Baking steps prior to, and occasionally after, UV curing are necessary to drive off the solvent. These steps add more time to the overall process and are often minimized to several minutes. Solvent-free formulations are most common when solvent usage for environmental reasons and baking steps are undesirable. Film deposition usually requires processes other than spin-coating that can deliver desired film thicknesses, such as draw bar coating.

The refractive index of the imprinted formulation is designed to match or closely match the refractive indices of the substrate. Values of refractive index of the nanocomposite layer are preferably 1.60-2.10 and above to correspond with the refractive indices of high-refractive index glass and other specialized metal oxide surfaces in the visible wavelengths. Zirconia nanocrystals can only achieve values in this specified range up to 1.8, because of the inherent bulk zirconia refractive indices of 2.1-2.2 from 400 to 700 nm. Formulations comprising anatase titania nanocrystals can reach values of refractive index up to 2.1 or more, because of the refractive index range of 2.49-2.56 for the bulk anatase TiO₂. Formulations comprising rutile titania nanocrystals can reach values of refractive index up to 2.2 or more, because of the refractive index range of 2.6-2.9 for the bulk rutile TiO₂. When synthesized and capped with appropriate capping agents for dispersibility within particle sizes of 1-100 nm, preferably 4-30 nm, capped zirconia and titania can have refractive index values from 1.8-2.3 from 400 to 700 nm. When properly dispersed in appropriate monomers, oligomers and polymers, capped nanocrystals, at weight loadings of 35-90% can yield stable dispersions that can make films with refractive index values ranging from 1.6-2.1 or higher within the visible light spectrum. Purely organic polymers and nanocomposites comprising inorganic oxides with lower indices of refraction, such as silicon dioxide and germanium oxide, would either not be able to achieve values in the desired range, would consist of atomic constituents that could cause absorption or would require very high weight loadings to reach the final desired high refractive index values. Higher weight loadings of nanoparticles typically give rise to very high viscosities that eliminate certain formulations for NI applications, because of the material's inability to flow into the stamps as previously mentioned.

Nanocomposite formulations intended for index matching with other layers in devices such as displays (OLED, LCD, reflective and other), AR/VR devices and lenses are required to be transparent unless a scattering layer is desired. Formulation and film transparencies are strongly related to the nanoparticle size and distribution. By synthesizing and maintaining particle sizes of 30 nm or less, the formulation and films can allow high transmission of light (% T>95%) over the visible spectrum. Particles that are greater than 40 nm tend to scatter light unfavorably, causing overall lower transmissions through the materials. Aggregated particles can also give rise to this scattering issue if dispersions are not stable over time. Unstable dispersions likely have particles that are not capped appropriately with enough or the right capping agents for the intended organic matrix. In addition, having a small particle size narrow size distribution and no aggregates in a formulation allows for high nanocrystal loading without significantly increasing the viscosity, resulting in high refractive index, high transparency, low viscosity formulations.

### BRIEF SUMMARY

The present disclosure provides formulations that are nanoimprintable and/or inkjet-printable, solvent-containing or solvent-free with workable viscosity values, high refractive index, UV-curable and comprise capped zirconium oxide and/or titanium dioxide nanocrystals in an organic matrix with curing agent. Said formulations optionally additionally comprise any of the following components: a wetting agent, an antioxidant, an adhesion promoter, a leveling agent, a dispersing agent, a plasticizer, a toughener, a thickener, a thinner, a dispersant, or a flexibilizer, or an organic dopant, or other functional additives. These formulations result in high-refractive, high-transparency nanocomposites.

The present disclosure provides the following non-limiting numbered embodiments as further examples of the disclosed technology:
1. A formulation comprising a dispersion of at least partially capped nanocrystals and a matrix comprising at least one of a solvent, monomer, oligomer, polymer or a crosslinker, optionally further comprising a curing agent, a surfactant, a wetting agent, an antioxidant, an adhesion promoter, a leveling agent, a dispersing agent, a plasticizer, a toughener, a thickener, a thinner, a dispersant, or a flexibilizer, or an organic dopant, or other functional additives. The nanocrystals typically comprise a metal oxide selected from zirconium oxide, titanium oxide, hafnium oxide, zinc oxide, tantalum oxide, niobium oxide, and combinations thereof.
2. The formulation of embodiment 1 wherein the matrix comprising one or more of acrylate and/or methacrylate monomers, reactive diluents, a curing agent and, optionally, at least one a surfactant or a wetting agent.
3. The formulation of any one of embodiments 1-2 wherein the average particle diameter of the at least partially capped nanocrystals is in the range from 1-30 nm (e.g., 5 nm, 10 nm, 15 nm, 20 nm, 30 nm, or any range or value between the recited values such as 5-30 nm or 5-20 nm, etc.) as measured by DLS or TEM.
4. The formulation of any one of embodiments 1-3 wherein said nanocrystals are at least partially capped with at least one capping agent selected from methyltrimethoxysilane, n-propyltrimethoxysilane, n-propyltriethoxysilane, noctyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl] trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, 3-glycidoxypropyltrimethoxysilane, vinyltrimethoxysilane, allyltrimethoxysilane, 1-hexenyltrimethoxysilane, 1-octenyltrimethoxysilane, (phenylaminomethyl) methyldimethoxysilane, N-phenylaminopropyltrimethoxysilane, 3-(4-pyridylethyl)thiopropyltrimethoxysilane, N-(3-trimethoxysilylpropyl)pyrrole, 2-(3-trimethoxysilylpropylthio) thiophene, (3-trimethoxysilylpropyl)diethylene triamine, 11-mercaptoundecyltrimethoxysilane, (2-diphenylphosphino) ethyldimethylethoxysilane, 2-(diphenylphosphino) ethyltriethoxysilane, 3-(diphenylphosphino) propyltriethoxysilane, heptanol, hexanol, octanol, benzyl alcohol, phenol, ethanol, propanol, butanol, oleylalcohol, dodecylalcohol, octadecanol, triethylene glycol monomethyl ether, octanoic acid, acetic acid, propionic acid, 2-[2-(2-methoxyethoxy) ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, 2-mercaptoethanol, 2-{2-[2-(2-mercaptoethoxy)ethoxy)ethoxy]ethoxy} ethanol, 2-(2-methoxyethoxy)ethanethiol, 1-octanethiol, sodium 2,3-dimercaptopropanesulfonate monohydrate, sodium dodecyl sulfate, dodecyl phosphonic acid, octylphosphonic acid, (11-mercaptoundecyl)phosphonic acid, (11-(acryloyloxy)undecyl)phosphonic acid, 11-methacryloyloxyundecylphosphonic acid, [2-[2-(2-methoxyethoxy)ethoxy]ethyl]phosphonic acid ethyl ester, and combinations thereof.
5. The formulations of any one of embodiments 1-4 include weight loadings of the zirconium oxide and/or titanium dioxide nanocrystals ranging from 5 to 95 wt % of the formulation.
6. The formulation of any one of embodiments 1-5 wherein said zirconium oxide and/or titanium dioxide nanocrystals are at least partially capped and the formulation further comprising monofunctional acrylate and/or methacrylate monomers with high refractive index, preferably >1.50 RI at 589 nm. Examples can include benzyl (meth)acrylate (BA and BMA), ethylene glycol phenyl ether (meth)acrylate (PEA and PEMA), 2-phenoxy benzyl acrylate (PBA), biphenyl methacrylate (BPMA), 2-phenylphenol methacrylate (PPMA), 2-phenylethyl acrylate (2-PEA), 2-(phenylthio)ethyl acrylate (PTEA), or combinations thereof.
7. The formulation of any one of embodiments 1-6 wherein zirconium oxide and/or titanium dioxide nanocrystals is at least partially capped and the formulation further comprising di-, tri-, tetra- and penta-functional acrylate and/or methacylate monomers, such as, 1,6-hexanediol di(meth)acrylate (HDDA and HDDMA), di(ethyleneglycol) di(meth)acrylate (DEGDA and DEGDMA), ethylene glycol diacrylate, glycerol 1,3-diglycerolate diacrylate, tri(propylene glycol) diacrylate, trimethylolpropane tri(meth)acrylate (TMPTA and TMPTMA), trimethylolpropane ethoxylate tri(meth)acrylate (EOTMPTA and EOTMPTMA), 1,6-hexanediol ethoxylate diacrylate, pentaerythritol tetraacrylate (PETA), bis(methacryloylthiophenyl)sulfide (BMTPS), tris(2-hydroxy ethyl)isocyanurate triacrylate (THEICTA) and dipentaerythritol penta-/hexa-acrylate (DPHA).
8. The formulation of any one of embodiments 1-7 wherein zirconium oxide and/or titanium dioxide nanocrystals is at least partially capped and the formulation further comprising reactive diluents, such as, 1-vinyl-2-pyrrolidone (NVP), N-vinyl caprolactam, 2-(2-vinyloxyethoxy) ethyl (meth)acrylate, isobutyl acrylate, styrene (STY), 4-methylstyrene (4MS), 4-vinylanisole (4VA) and divinylbenzene (DVB). For example, 1-vinyl-2-pyrrolidone is added to the formulation of any one of embodiments 1-8 to improve surface cure or tack. The weight percent of the reactive diluent is 10-80 wt % with respect to the total monomer content. The preferred weight percent of the reactive diluent is 25-70 wt % with respect to the total monomer content.
9. The formulation of any one of embodiments 1-8 wherein zirconium oxide and/or titanium dioxide nanocrystals is at least partially capped and the formulation further comprising di-, tri-, tetra-functional thiol crosslinkers, such as, trimethylolpropane tris(3-mercaptopropionate). The weight percent of the crosslinker is 1-80 wt % with respect to the total monomer content. The preferred weight percent of crosslinker is 1-50 wt % with respect to the total monomer content.
10. The formulation of embodiment 9 comprises one or more high-refractive index and/or sulfur-containing monomers and/or resins, preferably, the monomers and/or resins are selected from the compounds having the following structure and derivatives thereof:

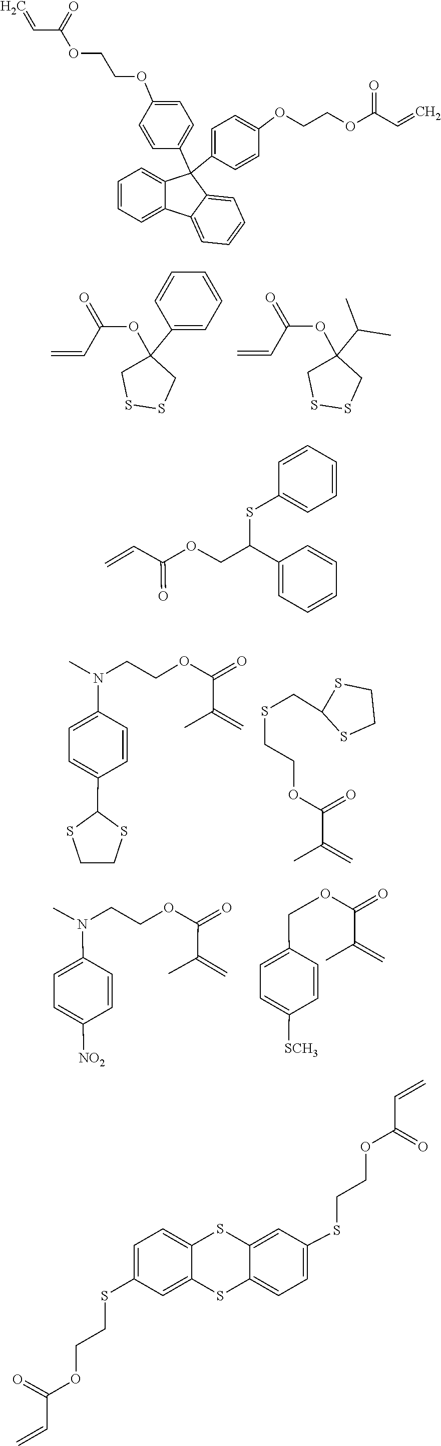

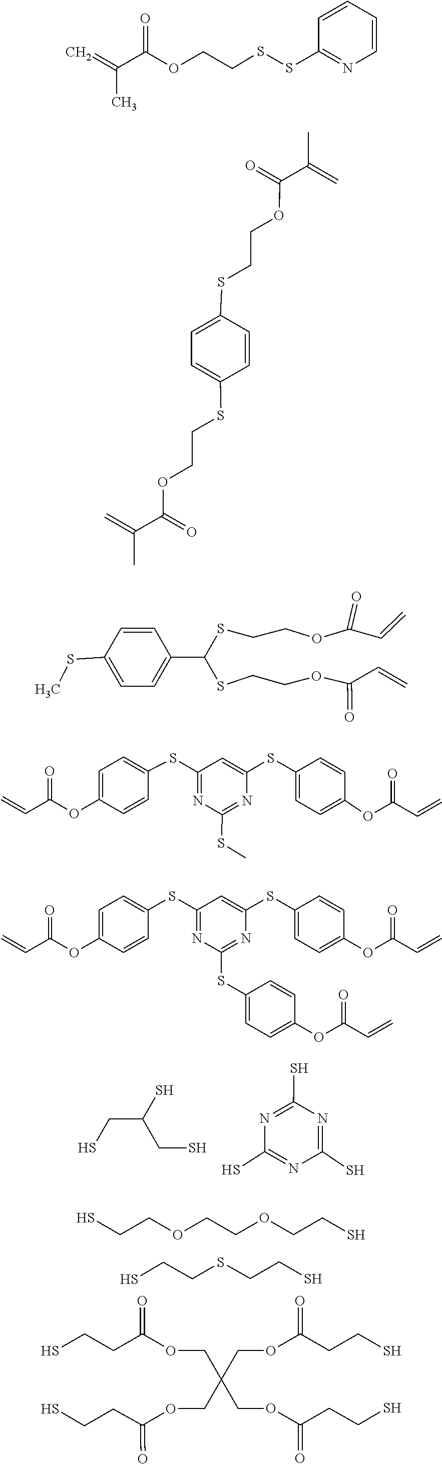

11. The formulation of any one of embodiments 1-10 wherein zirconium oxide and/or titanium dioxide nanocrystals is at least partially capped and the formulation further comprising reactive organic dopants, such as, phenanthrene (PhA) or 9-vinylcarbazole (NVCb). Concentrations of organic dopants can range from 1 to 50 wt %.
12. The formulation of any one of embodiments 1-11 wherein zirconium oxide and/or titanium dioxide nanocrystals is at least partially capped and the formulation further comprising surfactants or a combination of surfactants, such as, polyether-modified siloxanes, fluoro-surfactants, that are either non-reactive or reactive in the acrylate monomer system. Concentrations of said surfactants within the total formulation is in the range from 0.1-2.0 wt %. Preferred concentrations of said surfactants is in the range from 0.5-1.0 wt %.
13. The formulation of any one of embodiments 1-12 wherein zirconium oxide and/or titanium dioxide nanocrystals is at least partially capped and the formulation optionally further comprising scattering particles, such as, titanium dioxide, aluminum oxide, silicon dioxide, and low- and or high-index polymer particles. Scatterer particles sizes can range from 100-400 nm. Concentrations of said scatterers within the total formulation can range from 0.1-30.0 wt %. Preferred concentrations of said scatterers can range from 0.5-17.0 wt %.
14. The formulation of any one of embodiments 1-13 further comprising curing agents or photoinitiators, such as, Irgacure 184, Irgacure 819, ITX, TPO, Ebercryl P39, Esacure 1001M, and comprise synergists such as Ebercryl P115 and CN374, or a HALS type initiator. Concentrations of said photoinitiator within the total formulation is in the range from 0.1-20 wt % with respect to the monomer content. Preferred concentrations of said photoinitiators is in the range from 1.0-4.0 wt % with respect to the monomer content.
15. The formulation of any one of embodiments 1-14 wherein the formulation is solvent-free, i.e., with less than or equal to 5 wt % solvent present.
16. The formulations of any one of embodiments 1-15 where in the formulation contains solvent in the amount of greater than 10% by weight of the total formulation.
17. The solvent-free and/or solvent-containing formulation of any one of embodiments 15 and 16 and embodiments 34-51, wherein the viscosity of the formulation is within the range of 3-50,000 cP, when measured at 25° C. with a Brookfield RVDV II+ cone and plate viscometer. Preferred viscosities for inkjet-printing at 25° C. are 5-20 cP. When cartridge heating is applicable, viscosities at 25° C. can be 15-100 cP for cartridge temperatures between 35-100° C. Alternatively, the viscosity of the formulation is 5 cP-10 cP, or 10 cP-15 cP, 15 cP-20 cP, 20 cP-30 cP, 30 cP-50 cP, or 50 cP-100 cP, when measured at 25° C. For deposition methods other than inkjet-printing viscosities can range from 100 cP-1,000 cP, 1,000 cP-5,000 cP, 5,000 cP-10,000 cP or 10,000-50,000 cP.
18. The solvent-free and/or solvent-containing formulation of any one of embodiments 15 to 17 wherein the nanocrystal loading is 5-10%, 10-15%, 15-20%, 20-25%, 25-30%, 30-35%, 35-40%, 40-45%, 45-50%, 50-55%, 55-60%, 60-65%, 65-70%, 70-75%, 75-80%, 85-90%, 90-95% by weight of the formulation.
19. The solvent-free and/or solvent-containing formulation of any one of embodiments 15 to 17 and embodiments 34-51, wherein the refractive index is 1.52-1.56, 1.56-1.58, 1.58-1.60, 1.60-1.62, or 1.62-1.64, 1.64-1.66, or 1.66-1.68, or 1.68-1.70, or 1.70-1.72, or 1.72-1.74, or 1.74-1.76, or 1.76-1.78, or 1.78-1.80, or 1.80-1.82, or 1.82-1.84, or 1.84-1.86, or 1.86-1.88, or 1.88-1.90, 1.90-1.92, or 1.92-1.94, or 1.94-1.96, or 1.96-1.98, or 1.98-2.00, or 2.0-2.02, or 2.02-2.04, or 2.04-2.06, or 2.06-2.08, or 2.08-2.10 at 589 nm, 520 nm and/or 450 nm.
20. The solvent-free and/or solvent-containing formulation of any one of embodiments 15 to 17 and embodiments 34-51, wherein the % T of the formulation is 99%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% in the UVA, near UV, visible, near IR, and/or IR wavelengths.
21. The formulations of any one of embodiments 1-20 and embodiments 34-51, which can be deposited into films via a process selected from spin coating, slot-die coating, screen-printing, ink-jet printing, dip coating, draw-bar coating, roll-to-roll printing, spray coating, dispensing, volume casting, screen printing and any combination thereof.
22. The formulations of any one of embodiments 1-21 and embodiments 34-51, which is deposited onto an optically transparent hydrophilic substrate, such as fused silica, soda-lime, borosilicate glass, aluminum silicate, silicon nitride, indium tin oxide substrates, etc. Conversely, the formulations are deposited onto an optically transparent hydrophobic substrate, such as polyethylene terephthalate, polyimide, acrylic polymers, cyclic olefin copolymer, polycarbonate, polystyrene, and silicone.
23. The formulation of any one of embodiments 1 to 22 and embodiments 34-51, wherein the formulation can produce nanoimprinted structures (i.e., height, width, and pitch) on the order of 10 to 1000 nm.
24. The formulation of any one of embodiments 1 to 22 and embodiments 34-51, wherein the formulation can produce nanoimprinted structures having aspect ratios of 0.5:1 to 10:1.
25. A nanocomposite comprising a cured or partially cured formulation of any one of embodiments 1-24 and embodiments 34-51, wherein the formulation is cured via UV irradiation under UV LED sources with wavelengths at 365, 385, 395 and/or 405 nm or with a mercury “D”, “H” and/or “V” lamp(s). UV doses can range from 0.1-10 J/cm². Preferred UV doses are 0.5-2 J/cm². UV cure can occur under air or inert conditions, specifically nitrogen atmosphere.
26. A film of the nanocomposite of embodiment 25 wherein the film thickness ranges from 50 nanometers to 100 micrometers. Preferred film thickness values can range from 50 nanometers to 20 micrometers.
27. A film of the nanocomposite of any one of embodiments 25 and 26 characterized in that the film of at least 1 μm has a surface roughness of 5-4 nm, or 4-3 nm, or 3-2 nm, or 2-1 nm, or 1-0.5 nm, or 0.5-0.1 nm.
28. The nanocomposite of any one of embodiments 25-27 wherein the % T of the cured nanocomposite at thicknesses less than 10 microns is 99%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% in the UVA, near UV, visible, near IR, and/or IR wavelengths.
29. The nanocomposite of any one of embodiments 25-27 wherein the % T of the cured nanocomposite at thicknesses less than 1 microns is 99%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% in the UVA, near UV, visible, near IR, and/or IR wavelengths.
30. The nanocomposite of any one of embodiments 25-27 wherein the % T of the cured nanocomposite at thicknesses 10-30 microns is 99%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% in the UVA, near UV, visible, near IR, and/or IR wavelengths.
31. The nanocomposite of any one of embodiments 25-30 wherein refractive index of the cured nanocomposite is 1.54-1.56, 1.56-1.58, 1.58-1.60, 1.60-1.62, or 1.62-1.64, 1.64-1.66, or 1.66-1.68, or 1.68-1.70, or 1.70-1.72, or 1.72-1.74, or 1.74-1.76 or 1.76-1.78, or 1.78-1.80, or 1.80-1.82, or 1.82-1.84, or 1.84-1.86, or 1.86-1.88, or 1.88-1.90, 1.90-1.92, or 1.92-1.94, or 1.94-1.96, or 1.96-1.98, or 1.98-2.00, or 2.0-2.02, or 2.02-2.04, or 2.04-2.06, or 2.06-2.08, or 2.08-2.10 at 589 nm, 520 nm and/or 450 nm.
32. The nanocomposite of any one of embodiments 25-31 wherein the cured nanocomposite has a hardness of 1-5 MPa, or 5-20 MPa, or 20-50 MPa, or 50-100 MPa, or 100-150 MPa, or 150-200 MPa, or 200-250 MPa, 250-300 MPa, or 300-350 MPa, or 350-400 MPa as measured with nanoindentation.
33. The nanocomposite of any one of embodiments 25-32 wherein the cured nanocomposite has a modulus of 0.1-0.5 GPa, or 0.5-1.0 GPa, or 1.0-15 GPa, 1.5-2.0 GPa, or 2.0-2.5 GPa, or 2.5-3.0 GPa, or 3.0-3.5 GPa, or 3.5-4.0 GPa, or 4.0-4.5 GPa, 4.5-5.0 GPa, or 5.0-5.5 GPa, or 5.5-6.0 GPa, or 6.0-6.5 GPa, or 6.5-7.0 GPa, or 7.0-7.5 GPa, or 7.5-8.0 GPa, or 8.0-8.5 GPa, or 8.5-9.0 GPa, or 9.0-9.5 GPa, or 9.5-10.0 GPa as measured with nanoindentation.
34. A formulation comprising at least partially capped metal oxide nanocrystals (any of those described herein) in a matrix, wherein the matrix comprises (i) at least one monomer, oligomer, or polymer, e.g., any of those described herein (such as BPMA, PTEA, PBA, 2-PEA, BAC, HDDA, NVP, etc.); (ii) an optional crosslinker, e.g., any of those described herein (such as BMTPS, THEICTA, TMPTA, HR6042, etc.); (iii) a curing agent or polymerization initiator, such as a photoinitiator, e.g., any of those described herein (such as TPO, 1819, ITX, etc.); and optionally (iv) a solvent, such as PGMEA.
35. The formulation according to embodiment 34, wherein the at least partially capped metal oxide nanocrystals are at least partially capped ZrO₂, preferably, the average particle diameter of the at least partially capped ZrO₂ nanocrystals is in the range from 1-30 nm (e.g., 5 nm, 10 nm, 15 nm, 20 nm, 30 nm, or any range or value between the recited values such as 5-30 nm or 5-20 nm, etc.) as measured by DLS or TEM.
36. The formulation according to embodiment 35, comprising the solvent in an amount of 40-60% by weight of the formulation.
37. The formulation of embodiment 36, comprising by weight of the formulation, 25-40% (e.g., 30-40%) by weight of the at least partially capped metal oxide nanocrystals, 3-15% (e.g., 5-10%) by weight of the at least one monomer, oligomer, or polymer, 1-15% (e.g., 2-10%) by weight of the crosslinker, and 0.1-2% (e.g., 0.1-1% such as 0.5-1%) by weight of the curing agent or polymerization initiator.
38. The formulation according to embodiment 35, which is solvent-free, i.e., the solvent is present in no greater than 5% by weight of the formulation.
39. The formulation of embodiment 38, comprising by weight of the formulation, 60-80% (e.g., 64-70%) by weight of the at least partially capped metal oxide nanocrystals, 10-30% (e.g., 15-27%) by weight of the at least one monomer, oligomer, or polymer, 5-20% (e.g., 8-14%) by weight of the crosslinker, and 0.1-2% (e.g., 0.5-1.5% such as 1%) by weight of the curing agent or polymerization initiator.
40. The formulation of embodiment 38, comprising by weight of the formulation, 20-60% (e.g., 35-45%) by weight of the at least partially capped metal oxide nanocrystals, 30-70% (e.g., 40-60% or 46-56%) by weight of the at least one monomer, oligomer, or polymer, 0-20% (e.g., 0-10%, 5-15% etc.) by weight of the crosslinker, and 0.1-5% (e.g., 1-3%) by weight of the curing agent or polymerization initiator.
41. The formulation of embodiment 40, further comprising a synergist (e.g., any of those described herein), such as CN374, in an amount of 0.1-10%, such as 1-5% or 3% by weight of the formulation.
42. The formulation of embodiment 40 or 41, further comprising a surfactant (e.g., any of those described herein), such as BYK surfactant, in an amount of 0.1-10%, such as 0.5-2% by weight of the formulation.
43. The formulation according to embodiment 34, wherein the at least partially capped metal oxide nanocrystals are at least partially capped TiO₂, preferably, the average particle diameter of the at least partially capped TiO₂ nanocrystals is in the range from 1-30 nm (e.g., 5 nm, 10 nm, 15 nm, 20 nm, 30 nm, or any range or value between the recited values such as 5-30 nm or 5-20 nm, etc.) as measured by DLS or TEM.
44. The formulation according to embodiment 43, comprising the solvent in an amount of 10-85% by weight of the formulation.
45. The formulation of embodiment 44, comprising by weight of the formulation, 10-80% (e.g., 10%, 30%, 40%, 50%, 60%, 70%, 75%, or any range or value between the recited values, such as 30-50%, 20-60%, etc.) by weight of the at least partially capped metal oxide nanocrystals, 3-20% (e.g., 5-10%, 4-15%, etc.) by weight of the at least one monomer, oligomer, or polymer, 0.5-15% (e.g., 1-5%, 5-10%, 2-10%, etc.) by weight of the crosslinker, and 0.1-2% (e.g., 0.1-1% such as 0.5-1%) by weight of the curing agent or polymerization initiator.
46. The formulation according to embodiment 43, which is solvent-free, i.e., the solvent is present in no greater than 5% by weight of the formulation.
47. The formulation of embodiment 46, comprising by weight of the formulation, 60-80% (e.g., 60-74%) by weight of the at least partially capped metal oxide nanocrystals, 10-40% (e.g., 15-30%) by weight of the at least one monomer, oligomer, or polymer, 5-20% (e.g., 8-12%) by weight of the crosslinker, and 0.1-2% (e.g., 0.5-1.5% such as 1%) by weight of the curing agent or polymerization initiator.
48. The formulation of embodiment 46, comprising by weight of the formulation, 20-60% (e.g., 40-50%) by weight of the at least partially capped metal oxide nanocrystals, 30-70% (e.g., 40-60% or 46-56%) by weight of the at least one monomer, oligomer, or polymer, 0-20% (e.g., 0-10%, 4%, 5-15% etc.) by weight of the crosslinker, and 0.1-5% (e.g., 3%, 1-3%, etc.) by weight of the curing agent or polymerization initiator.
49. The formulation of embodiment 48, further comprising a surfactant (e.g., any of those described herein), such as BYK surfactant, in an amount of 0.1-10%, such as 0.5-2% by weight of the formulation.
50. The formulation of any one of embodiments 34-49, which is nanoimprintable.
51. The formulation of any one of embodiments 34-49, which is inkjet-printable.
52. A nanocomposite prepared from the formulation of any one of embodiments 34-51.
53. A formulation according to any of those described in Examples 1-6 of this application, including formulations A1, A2, A3, A4, A5, B1, B2, C1, C2, C3, C4, C5, C6, C7, C8, C9, C10, C11, C12, C13, C14, C15, C16, C17, C18, C19, C20, C21, D1, D2, D3, D4, E1, E2, E3, E4, E5, F1, and F2.
54. A nanocomposite prepared from any of the formulations described herein, such as those described in Examples 1-6 of this application.
55. Any of the formulations and nanocomposite described herein in the originally filed claims 1-46.
56. A device comprising any of the nanocomposite described herein.

It is to be understood that both the foregoing summary and the following detailed description are exemplary and explanatory only, and are not restrictive of the invention herein.

### BRIEF DESCRIPTION OF THE FIGURES

FIG. 1. Core particle size of TiO₂ nanocrystals by TEM (a) 5 nm core TiO₂ (c) 15 nm core TiO₂ and (e) 5 nm core ZrO₂ and Particle size distribution curves by way of dynamic light scattering (DLS) in (b), (d) and (f) of these nanocrystals dispersed in PGMEA, respectively.

FIG. 2. Pictures showing NIL capability for Formulation A1 (right) and A2 (left) formulations

FIG. 3. Pictures showing NIL capability for Formulation B1 (a) and B2 (c) and table showing the fidelity of the structures to the master for formulation B1 NIL patterns (b).

FIG. 4. Pictures showing NIL capability for Formulation C1 (top row and bottom left), C2 (bottom middle) and C3 (bottom right)

FIG. 5. Pictures showing NIL capability for Formulation D1 and D2, (a) triangular structures, top D1, bottom D2, (b) pillars, top D1, bottom D2

### DETAILED DESCRIPTION

### Characterization

Formulations and nanocomposites of the present disclosure can be analyzed according to methods known to a person of ordinary skill in the art. Exemplified analysis are shown herein, including those shown in the Examples section herein.

The presently disclosed formulations are analyzed using a TA instrument Q500 thermal gravimetric analyzer (TGA) to determine the inorganic solid content. The TGA is run with nanocrystal dispersions in a solvent with boiling point <200 C to determine the organic content of capped nanocrystals. The percent mass at 200° C. relative to the initial mass is regarded as capped nanocrystals and the percent mass at 700° C. relative to the initial mass is regarded as inorganic portion of the capped nanocrystal, i.e. inorganic solid content. The percent organics of capped nanocrystals (% Org) is defined as the difference between the percent mass at 200° C. (M200C) and at 700° C. (M700C) divided by the percent mass at 200° C.:

$$\% Org = \frac{M 200 C - M 700 C}{M 200 C} \times 100 \%$$

For a nanocomposite or a formulation, the percent solids (% S) is calculated from the inorganic content of the nanocomposite and organic content of the capped nanocrystals measured in solvent:

$$\% S = \frac{M 700 C}{100 \% - \% Org} \times 100 \%$$

The capped nanocrystals of the presently disclosed formulation constitute less than 10% by weight of the total formulation, or 10%-20% by weight of the total formulation, or 20%-30% by weight of the total formulation, or 30%-40% by weight of the total formulation, or 40%-50% by weight of the total formulation, or 50%-60% by weight of the total formulation, or 60%-70% by weight of the total formulation, or 70%-80% by weight of the total formulation, or 80%-90% by weight of the total formulation, or 90%-93% by weight of the total formulation.

The capped nanocrystals of the presently disclosed nanocomposite constitute less than 10% by weight of the total nanocomposite, or 10%-20% by weight of the total nanocomposite, or 20%-30% by weight of the total nanocomposite, or 30%-40% by weight of the total nanocomposite, or 40%-50% by weight of the total nanocomposite, or 50%-60% by weight of the total nanocomposite, or 60%-70% by weight of the total nanocomposite, or 70%-80% by weight of the total nanocomposite, or 80%-90% by weight of the total nanocomposite, or 90%-93% by weight of the total nanocomposite.

Optical transmittance is a common technique to evaluate the quality of a dispersion, formulation, and a nanocomposite film or coating. Light propagating through a sample can be absorbed, scattered, or transmitted. The normal transmittance at a given wavelength is defined as Tn=I/I₀, where I₀ is the intensity of incident light and I is the intensity of the light in the forward direction collected by the detector, which includes both light that is transmitted without scattering and light that is scattered into the forward direction. Theoretically the forward direction is defined as the same direction of the incident light, and however the detector usually collects light within a small solid angle around this direction due to the finite size of the detector. This transmittance is called normal transmittance or just transmittance, throughout this disclosure. The absorbance of a sample, i.e., optical density (OD), at a given wavelength is defined as:

$$OD = - {log}_{l 0} \frac{I}{{I}_{0}}$$

When measuring normal transmittance, measurement artifacts, such as Fresnel reflections off various interfaces and absorption by cuvette walls, need to be accounted for and removed. This can be taken care of by using a reference, either by measuring the sample and reference side by side in the instrument, or by measuring the sample and reference sequentially and then correcting the data mathematically afterward. The liquid nanocrystal dispersion sample can be measured in a cuvette made of glass, quartz, or plastic, and due to the finite thickness of the cuvette wall, there are four interfaces where Fresnel reflections can occur, and two walls where absorption can occur. Using a cuvette with same material, wall thickness, and path length as the reference produce results with enough accuracy.

For thin-film nanocomposites, the coated substrate is measured against a blank substrate made of same material with same thickness and surface smoothness, either side by side, or sequentially, to correct absorption and reflection at interfaces. Because the coating has a different refractive index than the substrate and air, the reflection off the front face of the film and the substrate maybe slightly different, often resulting in higher than 100% transmittance based on the algorithm used by the spectrophotometer. The effect can be corrected but the step is complicated, and the error is usually small. For convenience, the transmittance data shown in this disclosure are as measured without correction.

Light that is neither transmitted nor scattered nor reflected is absorbed. The absorbance can be calculated by subtracting the transmitted, scattered, and reflected light from the incident light.

The optical transmittance at 450 nm of the presently disclosed formulation with no curing agent, when measured in a cuvette with 1 cm path length using a Perkin Elmer Lambda 850 spectrophotometer, is 99%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10%.

The optical transmittance at 400 nm of the presently disclosed formulation with no curing agent, when measured in a cuvette with 1 cm path length using a Perkin Elmer Lambda 850 spectrophotometer, is 99%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10%.

The optical transmittance at 450 nm of the presently disclosed nanocomposite, when measured as a 1 um (micrometer) thick film on a transparent substrate using a Perkin Elmer Lambda 850 spectrophotometer, is 99%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10%.

The optical transmittance at 400 nm of the presently disclosed nanocomposite, when measured as a 1 um thick film on a transparent substrate using a Perkin Elmer Lambda 850 spectrophotometer, is 99%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10%.

Formulations of the present disclosure have a viscosity of about 1 cP to 100,000, 100 cP to 100,000 cP, or 1 cP to about 12,000 cP. Formulations of the present disclosure have a viscosity of about 1 cP, about 2 cP, about 5 cP, about 10 cP, about 15 cP, about 20 cP, about 25 cP, about 30 cP, about 40 cP, about 50 cP, about 60 cP, about 75 cP, about 100 cP, about 200 cP, 500 cP, or about 1,000 cP, or about 1,500 cP, or about 2,000 cP, or about 2,500 cP, or about 3,000 cP, or about 3,500 cP, or about 4,000 cP, or about 4,500 cP, or about 5,500 cP, or about 6,000 cP, or about 6,500 cP, or about 7,000 cP, or about 7,500 cP, or about 8,000 cP, or about 8,500 cP, or about 9,000 cP, or about 9,500 cP, or about 10,000 cP, 11,000 cP, 12,000 cP, when measured with a Brookfield RVDV II+ cone and plate viscometer measured at 25 C.

### Formulation Components and Properties

The present disclosure provides solvent-containing and/or solvent-free, nanoimprintable, high-transparency, high-RI, formulations comprising at least partially capped zirconium oxide and/or titanium dioxide nanocrystals dispersed in a monomer, oligomer, polymer or mixtures thereof. Said formulations optionally include, a curing agent, an adhesion promoter, a wetting agent, a leveling agent, a dispersing agent, a viscosity modifier, organic dopants and an antioxidant. These formulations make it possible to produce nanocomposites and thin film coatings with high refractive indices and high optical transparency. These formulations, specific to inkjet printing applications, shall have a strong resistance to inkjet nozzle faceplate wetting and appropriate wettability to desired substrates. A liquid wets to a specific solid surface and a contact angle forms once the liquid has reached equilibrium. Very low values of contact angle are typically less than 10°, and the liquid has high wettability with said surface. With high wettability uniform coatings can be achieved. Contact angles greater than 45° are suggestive of partially wetted or non-wetted cases. For such cases irregular surfaces and possible lens printing are possible outcomes and are often indicative of high surface tension liquids on low surface energy surfaces.

The resultant nanocomposite films shall have moderate to high degrees of cure, good adhesion to the intended substrates and good film uniformity.

The capped zirconia and titania nanocrystals of the present disclosure have a narrow size distribution, with an average size range of 1 to 100 nm, or 3-30 nm, preferably 4-20 nm measured with Transmission Electron Microscopy (TEM).

The capped zirconia and titania nanocrystals of the present disclosure are, for example, monodispersed with an average size of less than 100 nm, preferably <60 nm, measured with a Malvern Zetasizer Nano S Dynamic Light Scattering (DLS) instrument when dispersed in a solvent, such as PGMEA, at a concentration less than or equal to 5% by weight. The DLS measures the particle size together with the solvent shell surrounding the nanocrystal. The capped nanocrystals of present disclosure maintain dispersibility or remain agglomeration-free in a polymer or monomer matrix. Such physical characteristics of the presently disclosed materials not only reduce light scattering but also make for improved processability.

The capped nanocrystals of presented disclosure are prepared by a method described in U.S. Pat. No. 8,592,511 B2, and PCT/US2019/062439 (published as WO2020/106860A1), the entire contents of each of which are incorporated herein by reference.

The nanocrystals of the present disclosure are at least partially capped with specific functional group, also referred to as capping agents, or capping groups. These specific functional groups are grafted to the surface of the nanocrystals. The capping reaction can be performed in the presence of water. As used herein capped nanocrystals and at least partially capped nanocrystals are functionally equivalent.

The capping agent of capped nanocrystals in the presently disclosed formulation includes organosilanes, organocarboxylic acids and/or organoalcohols. Examples of capping agents include methyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl] trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, 3-glycidoxypropyltrimethoxysilane, vinyltrimethoxysilane, allyltrimethoxysilane, 1-hexenyltrimethoxysilane, 1-octenyltrimethoxysilane, (phenylaminomethyl) methyldimethoxysilane, N-phenylaminopropyltrimethoxysilane, 3-(4-pyridylethyl)thiopropyltrimethoxysilane, N-(3-trimethoxysilylpropyl)pyrrole, 2-(3-trimethoxysilylpropylthio) thiophene, (3-trimethoxysilylpropyl)diethylene triamine, 11-mercaptoundecyltrimethoxysilane, (2-diphenylphosphino) ethyldimethylethoxysilane, 2-(diphenylphosphino) ethyltriethoxysilane, 3-(diphenylphosphino) propyltriethoxysilane, heptanol, hexanol, octanol, benzyl alcohol, phenol, ethanol, propanol, butanol, oleylalcohol, dodecylalcohol, octadecanol, triethylene glycol monomethyl ether, octanoic acid, acetic acid, propionic acid, 2-[2-(2-methoxyethoxy) ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, 2-mercaptoethanol, 2-{2-[2-(2-mercaptoethoxy)ethoxy)ethoxy]ethoxy} ethanol, 2-(2-methoxyethoxy)ethanethiol, 1-octanethiol, sodium 2,3-dimercaptopropanesulfonate monohydrate, sodium dodecyl sulfate, dodecyl phosphonic acid, octylphosphonic acid, (11-mercaptoundecyl)phosphonic acid, (11-(acryloyloxy)undecyl)phosphonic acid, 11-methacryloyloxyundecylphosphonic acid, [2-[2-(2-methoxyethoxy)ethoxy]ethyl]phosphonic acid ethyl ester, and combinations thereof.

The acrylic monomer, oligomer, and/or polymer of presently disclosed formulation include benzyl (meth)acrylate (BA and BMA), trimethylolpropane tri(meth)acrylate (TMPTA and TMPTMA), trimethylolpropane ethoxylate tri(meth)acrylate (EOTMPTA and EOTMPTMA), 1,6-hexanediol di(meth)acrylate (HDDA and HDDMA), di(ethyleneglycol) di(meth)acrylate (DEGDA and DEGDMA), ethylene glycol diacrylate, glycerol 1,3-diglycerolate diacrylate, tri(propylene glycol) diacrylate, 1,6-hexanediol ethoxylate diacrylate, ethylene glycol phenyl ether (meth)acrylate (PEA and PEMA), 2-hydroxy-3-phenoxypropyl acrylate (HPPA), 2-hydroxy-3-phenoxypropyl methacrylate (HPPMA), 2-phenoxy benzyl acrylate (PBA), biphenyl methacrylate (BPMA), 2-phenylphenol methacrylate (PPMA), isobutyl acrylate (IBA), 2-phenylethyl acrylate (2-PEA), 2-(phenylthio)ethyl acrylate (PTEA), tris(2-hydroxy ethyl)isocyanurate triacrylate (THEICTA), high-refractive index, and/or sulfur-containing monomers and resins that are derived from or have the molecular structures:

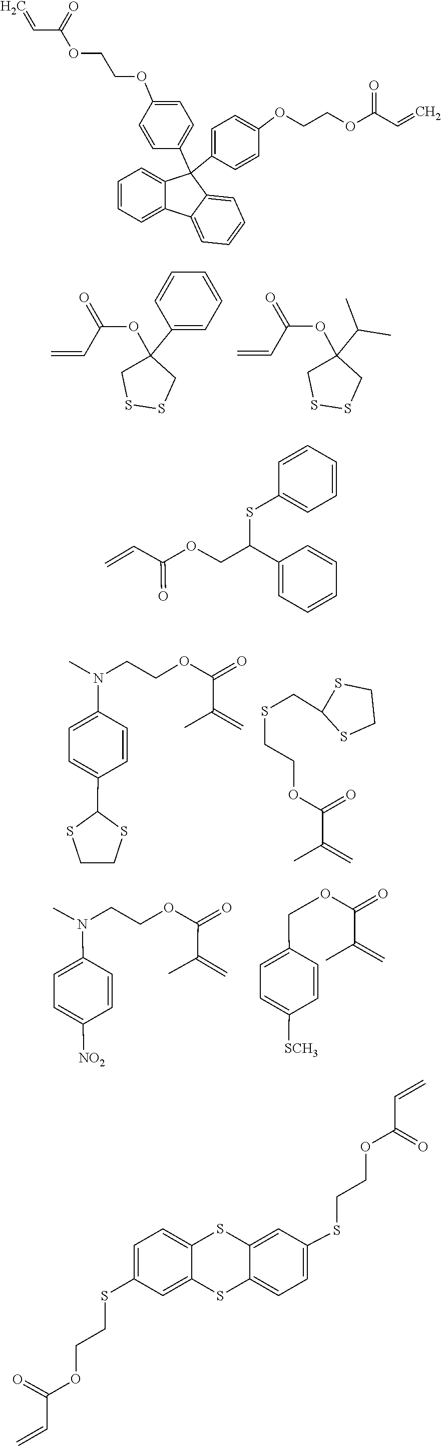

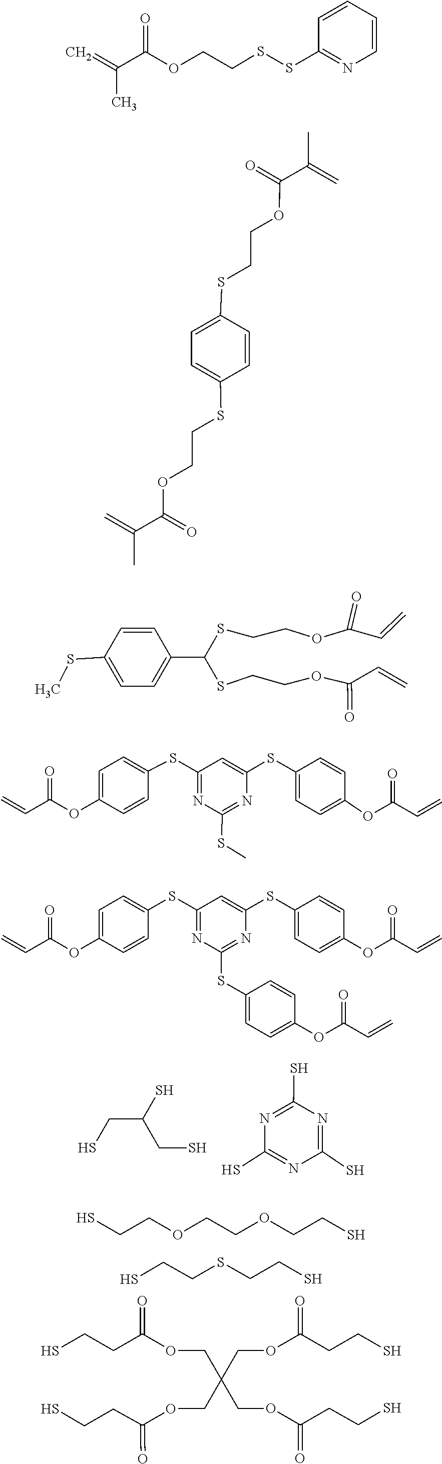

or combinations thereof.

The vinyl monomer, oligomer, and/or polymer of presently disclosed formulation include N-vinyl pyrrolidone (NVP), phenyl norborene, styrene (STY), 4-methylstyrene, 4-vinylanisole, divinylbenzene or combinations thereof.

Curing agents of the presently disclosed formulation comprise a photopolymerization initiator. Any photopolymerization initiator, provided that it doesn't limit optical and physical performance of the nanocomposite, can be used as long as it is capable of producing an active species, such as a radical with light (UV) energy. Photopolymerization initiator curing agents include amines such as Ebecryl® P115, CN374, Esacure 1001M or benzophenone and its derivatives such as Ebecryl® P39, benzophenone, SpeedCure BEM (Lambson USA Ltd, Rutherford, CT, USA) or organophosphines such as diphenyl(2,4,6-trimethylbenzoyl)-phosphine oxide (TPO), Irgacure® 819, or Irgacure® 184 (BASF USA, Florham Park, NJ, USA), or ITX. The formulation comprises a single photopolymerization initiator or any combination thereof. Although the formulations described herein focus on the application of UV radiation for cure, thermal cure is entirely possible with appropriate thermo-initiators, such as 2,2-Azobis(2-methylpropionitrile) (AIBN).

A combination of more than one curing agents are advantageous in certain circumstances known to one of ordinary skill.

The amount of curing agent of presently disclosed formulation is in an amount of less than 0.5% by total weight of the monomer, oligomer, and/or polymer, or 0.5%-1% by total weight of the monomer, oligomer, and/or polymer, or 1%-2% by total weight of the monomer, oligomer, and/or polymer, or 2%-3% by total weight of the monomer, oligomer, and/or polymer, or 3%-4% by total weight of the monomer, oligomer, and/or polymer, or 4%-5% by total weight of the monomer, oligomer, and/or polymer, or 5%-6% by total weight of the monomer, oligomer, and/or polymer, or 6%-7% by total weight of the monomer, oligomer, and/or polymer, or 7%-8% by total weight of the monomer, oligomer, and/or polymer, or 8%-15% by total weight of the monomer, oligomer, and/or polymer.

The adhesion promoter, if present is selected from organo-metallic compounds, such as organo functional silanes, or from functionalized monomers and oligomers. Some organo functional silane adhesion promoters that are suitable contain amino or methacryloxy groups. Exemplary silane adhesion promoters include, but are not limited to 3-aminopropyltriethoxysilane, 3-[(methacryloyloxy)propyl]trimethoxysilane, ureidopropyltrimethoxysilane, and trimethoxy[3-(methylamino)propyl]silane. Functionalized monomer and oligomer adhesion promoters include, but are not limited to, CN820, CN146 (Sartomer Americas, Exton, PA, USA), SR9051, SR9053 (Sartomer Americas, Exton, PA, USA), and Ebecryl 171 (Allnex USA Inc., Wallingford, CT, USA).

Adhesion promoters of the presently disclosed formulation is present in an amount of less than 0.5% by weight of the monomer, oligomer, and/or polymer, or 0.5-1% by weight of the monomer, oligomer, and/or polymer, or 1-5% by weight of the monomer, oligomer, and/or polymer, or 5-10% by weight of the monomer, oligomer, and/or polymer, or 10-15% by weight of the monomer, oligomer, and/or polymer, or 15-30% by weight of the monomer, oligomer, and/or polymer.

A surfactant, which can act as a wetting agent, leveling agent, defoaming agent and dispersing agent is present to reduce the surface tension of the formulation and thereby improve the flow properties of the formulation to produce a more uniform dried coating surface. The surfactant is non-ionic, anionic, or a combination thereof. Representative examples of suitable wetting agents include but are not limited to siloxane surfactants such as BYK-331, BYK-377, BYK-378, (BYK Chemie, GMBH) and fluoro-surfactants such as Novec 4430, Novec 4432, and Novec 4434 (3M, St. Paul, MN, USA), and Capstone FS-3100 (The Chemours Company, Wilmington, DE, USA).

Examples of leveling agent, if present, are a polyacrylate compound such as BYK-352, BYK-353, BYK-356, and BYK-361N; an aralkyl modified polymethylalkylsiloxane, such as BYK-322, BYK-323, and BYK-350 (BYK Chemie, GMBH) and a polyether-modified, acryl functional siloxane, such as BYK-UV3530. Examples of the dispersing agent include, without limitation, polyalkylene glycols and esters thereof, polyoxyalkylenes, polyhydric alcohol ester alkylene oxide addition products, alcohol alkylene oxide addition products, sulfonate esters, sulfonate salts, carboxylate esters, carboxylate salts, alkylamide alkylene oxide addition products, alkyl amines, and the like, and are used singularly or as a mixture of two or more. Commercially available examples of the dispersing agent include without limitation DISPERBYK-101, DISPERBYK-130, DISPERBYK-140, DISPERBYK-160, DISPERBYK-161, DISPERBYK-162, DISPERBYK-163, DISPERBYK-164, DISPERBYK-165, DISPERBYK-166, DISPERBYK-170, DISPERBYK-171, DISPERBYK-182, DISPERBYK-2000, DISPERBYK-2001 (BYK Chemie, GMBH), Solsperse 32000, Solsperse 36000, Solsperse 28000, Solsperse 20000, Solsperse 41000, and Solsperse 45000 (Lubrizol, Wickliffe, OH, USA).

The amount of surfactant of the presently disclosed formulation, for the purpose of improving wetting properties, is in amount of less than 0.05% by weight of the total formulation, or 0.05-0.1% by weight of the total formulation, or 0.1-0.5% by weight of the total formulation, or 0.5-1% by weight of the total formulation, or 1-2% by weight of the total formulation, or 2-5% by weight of the total formulation. For the purposes of aiding in dispersion the amount of surfactant of the presently disclosed formulation varies depending on the material being dispersed. The amount of dispersing agent is less than 3% by weight of the material being dispersed or 3-5% by weight of the material being dispersed, or 5-10% by weight of the material being dispersed, or 10-20% by weight of the material being dispersed, or 20-40% by weight of the material being dispersed, or 40-60% by weight of the material being dispersed, or 60-80% by weight of the material being dispersed, or 80-100% by weight of the material being dispersed, or 100-150% by weight of the material being dispersed.

Antioxidant agents of the presently disclosed formulation include at least one primary antioxidant. This primary antioxidant is selected from sterically hindered phenols, such as Irganox 1010, Irganox 1076, SongNox® 1076, SongNox® 2450 or phenolic phosphites such as SongNox® 1680 or phosphines such as Irgaphos 168 (BASF USA, Florham Park, NJ, USA) or aromatic secondary amines or hindered amines such as SongLight® 6220 (Songwon Americas, Friendwood, TX, USA).

Formulations of the present disclosure optionally contain at least one secondary antioxidant. This secondary antioxidant is preferably chosen from compounds comprising at least one unit formed from a sulfur atom linked to two carbon atoms. Representative examples of the secondary antioxidant are di(t-butyl) hydroxyphenylamino bisoctylthiotriazine and Irganox PS800 (BASF USA, Florham Park, NJ, USA).

The amount of anti-oxidant of presently disclosed formulation is less than 0.5% by weight of the total formulation, or 0.5%-1% by weight of the total formulation, or 1%-2% by weight of the total formulation, or 2%-3% by weight of the total formulation, or 3%-4% by weight of the total formulation, or 4%-5% by weight of the total formulation, or 5%-6% by weight of the total formulation, or 6%-7% by weight of the total formulation, or 7%-8% by weight of the total formulation or 8%-10% by weight of the total formulation.

The presently disclosed formulation can further comprise, plasticizer, toughener, thickener, thinner, dispersant, or flexibilizer, or other functional additives.

The presently disclosed formulation can further comprise a solvent. The choice of solvent depends entirely on the capped zirconia type and selected monomers, oligomers and polymers of the formulation. Examples of common solvents that range from low to high boiling point are alcohols, glycols, methyl acetates, ethyl acetates, esters, ketones, glycol ethers, glycol esters, such as propylene glycol monomethyl ether acetate (PGMEA), propylene glycol monomethyl ether (PGME), ethylene glycol monobutyl ether acetate, diethylene glycol monobutyl ether acetate, diethylene glycol butyl ether, diethylene glycol monoethyl ether acetate, dipropylene glycol methyl ether acetate, butoxy ethanol, butoxy propanol, ethoxy ethyl acetate, butoxy ethyl acetate, 2-(isopentyloxy)ethanol, 2-(hexyloxy)ethanol, diethylene glycol, diethylene glycol monomethyl ether, diethylene glycol monoethyl ether, triethylene glycol, triethylene glycol monomethyl ether, dipropylene glycol, dipropylene glycol monomethyl ether, and dipropylene glycol monoethyl ether, ethyl acetate, THF, acetone, any combination thereof.

Formulations of present disclosure have a tunable viscosity, and/or a viscosity that can be controlled by one or more of components of the formulation. Parameters that can control viscosity of the formulation include, but are not limited to, the average length, and molecular weight, of a monomer, oligomer, and/or polymer; as well as the presence of a solvent and the concentration of a solvent, the presence of a thickener (i.e., a viscosity-modifying component) and the concentration of a thickener, the particle size of a component present in the formulation, temperature, and combinations thereof.

The presently disclosed formulations are stable for more than 1 week, or more than 2 weeks, or more than 3 weeks, or more than 6 weeks, or more than 8 weeks, or more than 3 months, or more than 6 months, or more than 12 months, or more than 36 months, with no significant increase in viscosity. There should be no visible precipitation of capped nanocrystals, and the change in formulation viscosity should be less than 10%, or less than 20%, or less than 30%, or less than 40%, or less than 50%, or less than 100%. Furthermore, the change in the optical transmittance of the formulations should be less than 10% decrease in transmittance, or less than 20% decrease in transmittance, or less than 30% decrease in transmittance, or less than 40% decrease in transmittance, or less than 50% decrease in transmittance at 450 nm.

For the purposes of inkjet printing the jetting of the presently disclosed formulations are stable for more than 1 hour, for more than 8 hours, for more than 1 day, or more than 1 week with no significant increase in viscosity. The formulation does not solidify by way of drying or curing leading to clogging of printhead nozzles.

### Methods of Making a Solvent-Free or Solvent-Containing Nanocomposite Formulation

In some embodiments, the present disclosure provides the following exemplified methods for preparing a solvent-free or solvent-containing nanocomposite formulation herein.

1. A method of making a solvent-free nanocomposite formulation comprising a direct dispersion (directly dispersing nanocrystals in a media), method wherein capped zirconia and titania nanocrystals are separated from a solvent and dried under vacuum until the solvent content is less than 5% to form dry nanocrystals; mixing dry nanocrystals of at least partially capped zirconium oxide and titanium oxide nanocrystals in at least one monomer, oligomer, polymer or mixtures thereof and other formulation components by soaking, stirring, speed mixing, microfluidizing or other mixing methods.

In some embodiments, Method 1 can further comprise filtering said mixture to remove aggregates or other contaminants.

2. Another method of making a solvent free formulation comprising mixing dry powder of at least partially capped zirconium oxide and titanium oxide nanocrystals in at least one solvent by soaking, stirring, speed mixing, microfluidizing or other mixing methods to provide a nanocrystal solvent dispersion; mixing said dispersion with at least one monomer, oligomer, polymer or mixtures or monomers, oligomers and/or polymers and other formulation components to provide a solvent containing formulation; removing said solvent by evaporation or other solvent removal methods such as rotovap.

In some embodiments, Method 2 can further comprise filtering said solvent containing or solvent free formulation to remove aggregates or other contaminants.

Non-limiting useful solvents of Method 2 include ethyl acetate, methyl ethyl ketone, or other low boiling point solvents.

3. A method of making a solvent containing formulation comprising mixing dry powder of at least partially capped zirconium oxide and titanium oxide nanocrystals in at least one solvent by soaking, stirring, speed mixing, microfluidizing or other mixing methods to provide a nanocrystal solvent dispersion; mixing said dispersion with at least one monomer, oligomer, polymer or mixtures or monomers, oligomers and/or polymers and other formulation components to provide a solvent containing formulation. In some embodiments, Method 3 can further comprise filtering said solvent containing formulation to remove aggregates or other contaminants.

### Nanocomposite Properties

A nanocomposite is a film, coating, layer, lens on a substrate or free-standing structure. The present disclosure provides a nanocomposite comprising a mixture of an organic polymerizable matrix, a curing agent, and capped nanocrystals such as zirconia or titania nanocrystals wherein said capped nanocrystals are present in the nanocomposite in the amount of 20-95% by weight of the nanocomposite.

The capping agent of capped zirconia and titania nanocrystals in the presently disclosed nanocomposite include organosilanes, organocarboxylic acids and/or organoalcohols. Examples of capping agents include methyltrimethoxysilane, n-propyltrimethoxysilane, n-propyltriethoxysilane, noctyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl] trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, 3-glycidoxypropyltrimethoxysilane, vinyltrimethoxysilane, allyltrimethoxysilane, 1-hexenyltrimethoxysilane, 1-octenyltrimethoxysilane, (phenylaminomethyl) methyldimethoxysilane, N-phenylaminopropyltrimethoxysilane, 3-(4-pyridylethyl)thiopropyltrimethoxysilane, N-(3-trimethoxysilylpropyl)pyrrole, 2-(3-trimethoxysilylpropylthio) thiophene, (3-trimethoxysilylpropyl)diethylene triamine, 11-mercaptoundecyltrimethoxysilane, (2-diphenylphosphino) ethyldimethylethoxysilane, 2-(diphenylphosphino) ethyltriethoxysilane, 3-(diphenylphosphino) propyltriethoxysilane, heptanol, hexanol, octanol, benzyl alcohol, phenol, ethanol, propanol, butanol, oleylalcohol, dodecylalcohol, octadecanol, triethylene glycol monomethyl ether, octanoic acid, acetic acid, propionic acid, 2-[2-(2-methoxyethoxy) ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, 2-mercaptoethanol, 2-{2-[2-(2-mercaptoethoxy)ethoxy)ethoxy]ethoxy} ethanol, 2-(2-methoxyethoxy)ethanethiol, 1-octanethiol, sodium 2,3-dimercaptopropanesulfonate monohydrate, sodium dodecyl sulfate, dodecyl phosphonic acid, octylphosphonic acid, (11-mercaptoundecyl)phosphonic acid, (11-(acryloyloxy)undecyl)phosphonic acid, 11-methacryloyloxyundecylphosphonic acid, [2-[2-(2-methoxyethoxy)ethoxy]ethyl]phosphonic acid ethyl ester, and combinations thereof.

The inorganic solid content of the presently disclosed nanocomposite (e.g., nanocomposite coating or film) is analyzed using a TA instrument Q500 thermal gravimetric analyzer (TGA). The procedure is the same as described previously. The percent at 700° C. relative to the initial mass is regarded as inorganic portion of the formulation, i.e. solid content.

The inorganic solid content of the presently disclosed nanocomposite (e.g., nanocomposite coating or film) is 0-10% as measured by TGA, or 10-20% as measured by TGA, or 20-30% as measured by TGA, or 30-40% as measured by TGA, or 40-50% as measured by TGA, or 50-60% as measured by TGA, or 60-70% as measured by TGA, or 70-80% as measured by TGA, or 80-90% as measured by TGA, or 90-93% as measured by TGA.

The presently disclosed nanocomposite (e.g., nanocomposite coating or film) possesses a refractive index of 1.54-1.56, 1.56-1.58, 1.58-1.60, 1.60-1.62, or 1.62-1.64, 1.64-1.66, or 1.66-1.68, or 1.68-1.70, or 1.70-1.72, or 1.72-1.74, or 1.74-1.76 or 1.76-1.78, or 1.78-1.80, or 1.80-1.82, or 1.82-1.84, or 1.84-1.86, or 1.86-1.88, or 1.88-1.90, 1.90-1.92, or 1.92-1.94, or 1.94-1.96, or 1.96-1.98, or 1.98-2.00, or 2.00-2.02, or 2.02-2.04, or 2.04-2.06, or 2.06-2.08, or 2.08-2.10, or greater than 2.10 at 589 nm.

The presently disclosed nanocomposite (e.g., nanocomposite coating or film) possesses hardness values of 1-5 MPa, or 5-20 MPa, or 20-50 MPa, or 50-100 MPa, or 100-150 MPa, or 150-200 MPa, or 200-250 MPa, 250-300 MPa, or 300-350 MPa, or 350-400 MPa as measured with nanoindentation.

The presently disclosed nanocomposite (e.g., nanocomposite coating or film) possesses modulus values of 0.1-0.5 GPa, or 0.5-1.0 GPa, or 1.0-15 GPa, 1.5-2.0 GPa, or 2.0-2.5 GPa, or 2.5-3.0 GPa, 3.0-3.5 GPa, or 3.5-4.0 GPa, or 4.0-4.5 GPa, 4.5-5.0 GPa, or 5.0-5.5 GPa, or 5.5-6.0 GPa, or 6.0-6.5 GPa, or 6.5-7.0 GPa, or 7.0-7.5 GPa, or 7.5-8.0 GPa, or 8.0-8.5 GPa, or 8.5-9.0 GPa, or 9.0-9.5 GPa, or 9.5 to 10.0 GPa as measured with nanoindentation.

The presently disclosed nanocomposite (e.g., nanocomposite coating or film) possesses high optical transmittance of 99.9%-99%, or 99%-98%, or 98%-97%, or 97%-96%, or 96%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% at greater than or equal to 400 nm for films that are less than 20 microns thick. The transmittance of a film according to the present disclosure is normal transmittance measured with a Perkin-Elmer UV-Vis Lambda 850 spectrophotometer, wherein the nanocomposite is coated on an optically transparent substrate, such as fused silica or glass substrates, and a blank substrate of the same type and thickness is used as a reference. The presently disclosed nanocomposite possesses high optical transmittance of 99.9%-99%, or 99%-98%, or 98%-97%, or 97%-96%, or 96%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% at greater than or equal to 450 nm for films that are less than 20 microns thick.

The presently disclosed nanocomposite additionally demonstrates thermal stability at temperatures above 120° C., or above 175° C., or above 200° C., or above 250° C., or above 260° C., or above 300° C. The thermal stability is measured by subjecting the nanocomposite at designated temperature in air, nitrogen, or under vacuum for 5 minutes or longer, or 10 minute or longer, or 30 minutes or longer, or 60 minutes or longer, or 120 minutes or longer, without visually observable coloration, cracking, or delamination and less than 10% decrease in transmittance, or less than 20% decrease in transmittance, or less than 30% decrease in transmittance, or less than 40% decrease in transmittance, or less than 50% decrease in transmittance at 400 nm.

### A Method of Making a Nanocomposite

The present disclosure provides a method of making a nanocomposite using any of the presently disclosed formulations. A nanocomposite film is described herein containing a cured or partially cured formulation of the present disclosure. Said nanocomposite is cured or partially cured by UV or thermal curing techniques known to one of ordinary skill in the art.

The present disclosure provides a nanocomposite film as described herein wherein the film is produced by spin coating, slot-die coating, screen-printing, ink-jet printing, dip coating, draw-bar coating, roll-to-roll printing, spray coating, or any combination thereof.

### A Device

The present disclosure provides an LED, organic LED, touch screen, display, sensor, Augmented Reality, Virtual Reality or a solar cell device comprising an active component, said active component comprising or containing a nanocomposite of the present disclosure.

ZrO₂ and TiO₂ Nanocrystal Capping

The following exemplifies methods for preparing at least partially capped ZrO₂ and TiO₂ nanocrystals useful for embodiments of the present disclosure, such as a formulation or nanocomposite herein.

ZrO₂ and TiO₂ nanocrystals were synthesized via a solvothermal process similar to a process described in U.S. Pat. No. 8,592,511 B2 and PCT/US2019/062439 (published as WO2020/106860). As-synthesized ZrO₂ and TiO₂ nanocrystals were transferred to a flask. A solvent, such as PGMEA or toluene, was added at a 0.1:1-1:1, 1:1-1.25:1, 1.25:1-1.5:1, 1.5:1-1.75:1, 1.75:1-2:1, 2:1-2.25:1, 2.25:1-2.5:1, 2.5:1-2.75:1, 2.75:1-3:1, 3:1-4:1, 4:1-5:1, 5:1-6:1, 6:1-7:1, 7:1-8:1, 8:1-9:1, 9:1-10:1 solvent to nanocrystals. A primary capping agent was then added to the reaction flask at 0.1-5%, 5-10%, 10-15%, 15-20%, 20-25%, 25%-30%, 30%-35% of capping agent to wet cake by weight. This mixture was then heated by a first heating process to 50-60, 60-70, 70-80, 80-90, 90-100, 100-110, 110-120, 120-130° C. for 1-10, 10-20, 20-30, 30-40, 40-50, 50-60, 60-70, 70-80, 80-90, 90-100, 100-120 minutes.

Optionally a secondary capping agent was added to the reaction flask before or after the first heating process. The secondary capping agent was also added to the reaction flask at a at 0.1-5%, 5-10%, 10-15%, 15-20%, 20-25%, 25%-30%, 30%-35%, 35%-40%, 40%-45%, 45%-50%, 50%-55%, 55%-60%, 60%-70%, 70%-80%, 80%-90%, 90%-100% of capping agent to wet cake by weight. This mixture was then heated to 50-60, 60-70, 70-80, 80-90, 90-100, 100-110, 110-120, 120-130° C. for 1-10, 10-20, 20-30, 30-40, 40-50, 50-60, 60-70, 70-80, 80-90, 90-100, 100-120 minutes. Optionally water was then added to the reaction mixture after cooling the reaction mixture to 80 C at a 0.1-5%, 5-10%, 10-15%, 15-20%, 20-25%, 25%-30%, 30%-35%, of water to wet cake by weight. This mixture was heated at 80-90, 90-100, 100-110, 110-120, 120-130° C. for an additional 1-10, 10-20, 20-30, 30-40, 40-50, 50-60, 60-70, 70-80, 80-90, 90-100, 100-120 minutes The reaction mixture was then cooled to room temperature to provide capped nanocrystals. Capped nanocrystals can then be filtered through a 0.45 micron and then a 0.2-micron PTFE filter or optionally go through the following washing process.

The surface of ZrO₂ and/or TiO₂ nanocrystals of the present disclosure are optionally capped with at least one capping agent including, but not limited to methyltrimethoxysilane, n-propyltrimethoxysilane, n-propyltriethoxysilane, noctyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl] trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, 3-glycidoxypropyltrimethoxysilane, vinyltrimethoxysilane, allyltrimethoxysilane, 1-hexenyltrimethoxysilane, 1-octenyltrimethoxysilane, (phenylaminomethyl) methyldimethoxysilane, N-phenylaminopropyltrimethoxysilane, 3-(4-pyridylethyl)thiopropyltrimethoxysilane, N-(3-trimethoxysilylpropyl)pyrrole, 2-(3-trimethoxysilylpropylthio) thiophene, (3-trimethoxysilylpropyl)diethylene triamine, 11-mercaptoundecyltrimethoxysilane, (2-diphenylphosphino) ethyldimethylethoxysilane, 2-(diphenylphosphino) ethyltriethoxysilane, 3-(diphenylphosphino) propyltriethoxysilane, heptanol, hexanol, octanol, benzyl alcohol, phenol, ethanol, propanol, butanol, oleylalcohol, dodecylalcohol, octadecanol, triethylene glycol monomethyl ether, octanoic acid, acetic acid, propionic acid, 2-[2-(2-methoxyethoxy) ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, 2-mercaptoethanol, 2-{2-[2-(2-mercaptoethoxy)ethoxy)ethoxy]ethoxy} ethanol, 2-(2-methoxyethoxy)ethanethiol, 1-octanethiol, sodium 2,3-dimercaptopropanesulfonate monohydrate, sodium dodecyl sulfate, dodecyl phosphonic acid, octylphosphonic acid, (11-mercaptoundecyl)phosphonic acid, (11-(acryloyloxy)undecyl)phosphonic acid, 11-methacryloyloxyundecylphosphonic acid, [2-[2-(2-methoxyethoxy)ethoxy]ethyl]phosphonic acid ethyl ester, and combinations thereof.

The reaction mixture is optionally washed to remove excess capping agent and other by-products. The reaction mixture is precipitated by adding an anti-solvent such as heptane for a PGMEA solution or acetone for a toluene solution in a 0.1:1-1:1, 1:1-1.25:1, 1.25:1-1.5:1, 1.5:1-1.75:1, 1.75:1-2:1, 2:1-2.25:1, 2.25:1-2.5:1, 2.5:1-2.75:1, 2.75:1-3:1 anti-solvent to reaction mixture ratio weight-to-weight. This precipitate was centrifuged at 100-500, 500-1000, 100-1500, 1500-2000, 2000-2500, 2500-3000, 3000-3500, 3500-4000, 4000-4500, 4500-5000, 5000-5500, 5500-6000, 6000-6500, 6500-7000, 7000-7500, 7500-8000, 8000-8500, 8500-9000 rpm for 0-5, 5-10, 10-15, 15-20, 30-25, 25-30, 30-35, 35-40, 40-45, 45-50, 50-55, 55-60 minutes. The resulting supernatant was decanted and discarded. The solids were then dispersed in a solvent, such as toluene for non-polar capped nanocrystals or THF for polar capped nanocrystals. The dispersed solids were then precipitated in an anti-solvent again, such as heptane for a THF solution or acetone for a toluene solution in a 0.1:1-1:1, 1:1-1.25:1, 1.25:1-1.5:1, 1.5:1-1.75:1, 1.75:1-2:1, 2:1-2.25:1, 2.25:1-2.5:1, 2.5:1-2.75:1, 2.75:1-3:1 anti-solvent to reaction mixture ratio weight-to-weight. This precipitate was centrifuged at 100-500, 500-1000, 100-1500, 1500-2000, 2000-2500, 2500-3000, 3000-3500, 3500-4000, 4000-4500, 4500-5000, 5000-5500, 5500-6000, 6000-6500, 6500-7000, 7000-7500, 7500-8000, 8000-8500, 8500-9000 rpm for 0-5, 5-10,10-15, 15-20,30-25, 25-30, 30-35, 35-40, 40-45, 45-50, 50-55, 55-60 minutes. The resulting supernatant was decanted and discarded. This process is repeated if necessary. The solids were then placed in a vacuum oven to dry overnight.

The dried solids (capped nanocrystals) were then optionally re-dispersed in a 1:1 ratio of solids to solvent in PGMEA to create a 50% by weight loaded dispersion. The resulting dispersion was filtered through a 0.45 micron and then a 0.2-micron PTFE filter.

### Example Capped ZrO₂ Nanocrystals

The following further exemplifies methods for preparing at least partially capped ZrO₂ nanocrystals useful for embodiments of the present disclosure, such as a formulation or nanocomposite herein.

As-synthesized ZrO₂ nanocrystals, referred subsequently as “wet cake,” was transferred to a round bottom flask. PGMEA was then added by weight at a 0.370:1 solvent to wet-cake ratio. Following this step, methoxy(triethyleneoxy)propyltrimethoxysilane was added to the reaction flask at 10% by weight of the wet cake. 3-(acryloyloxy)propyltrimethoxysilane was then added to the reaction flask at 2% by weight of the wet cake. This mixture was heated to 120 degrees C. for 90 minutes with stirring to form the capped nanocrystals. Finally, the reaction mixture was cooled to RT.

The reaction mixture was then washed to remove excess capping agents and impurities. The reaction mixture was then precipitated with heptane as the anti-solvent using a 7:1 heptane to reaction mixture ratio weight-to-weight. This precipitate was centrifuged at 4500 rpm for 10 minutes. The resulting supernatant was decanted and discarded. The solids were then dispersed in THF using a 3:1 THF to solid ratio weight-to-weight. The dispersed solids were then precipitated in an anti-solvent again such as heptane in a 3:1 heptane to reaction mixture ratio weight-to-weight. This precipitate was centrifuged at 4500 rpm for 10 minutes. The resulting supernatant was decanted and discarded. The solids were then dispersed in THF using a 3:1 THF to solid ratio weight-to-weight. The dispersed solids were then precipitated a third time in an anti-solvent again such as heptane in a 3:1 heptane to reaction mixture ratio weight-to-weight. This precipitate was centrifuged at 4500 rpm for 10 minutes. The resulting supernatant was decanted and discarded. The solids were then placed in a vacuum oven to dry overnight.

The dried solids were redispersed into a solvent or a monomer and optionally filtered through a 0.45 micron and then a 0.2-micron PTFE filter.

### Example Capped TiO₂ Nanocrystals

The following further exemplifies methods for preparing at least partially capped TiO₂ nanocrystals useful for embodiments of the present disclosure, such as a formulation or nanocomposite herein.

As-synthesized TiO₂ nanocrystals, referred subsequently as “wet cake,” was transferred to a round bottom flask. PGMEA was then added by weight at a 1.857:1 solvent to wet-cake ratio. Following this step, methoxy(triethyleneoxy)propyltrimethoxysilane was added to the reaction flask at 15% by weight of the wet cake. This mixture was heated to 120 degrees C. for 40 minutes with stirring to form the partially capped nanocrystals. Methacryloxypropyltrimethoxysilane was then added to the reaction flask at 30% by weight of the wet cake and the mixture was heated at 120 degrees C. for an additional 30 minutes with stirring to form the capped nanocrystals. The reaction mixture was then cooled to 100 C, where water was then added at 5% by weight of the wet cake and the mixture was heated at 100 C for 30 minutes. Finally, the reaction mixture was cooled to RT.

The reaction mixture was then washed to remove excess capping agents and impurities. The reaction mixture was then precipitated with heptanes as the anti-solvent using a 3:1 heptanes to reaction mixture ratio weight-to-weight. This precipitate was centrifuged at 3000 rpm for 10 minutes. The resulting supernatant was decanted and discarded. The solids were then dispersed in THF using a 3:1 THF to solid ratio weight-to-weight. The dispersed solids were then precipitated in an anti-solvent again such as heptanes in a 3:1 heptanes to reaction mixture ratio weight-to-weight. This precipitate was centrifuged at 3000 rpm for 10 minutes. The resulting supernatant was decanted and discarded. The solids were then dispersed in THF using a 3:1 THF to solid ratio weight-to-weight. The dispersed solids were then precipitated a third time in an anti-solvent again such as heptanes in a 3:1 heptanes to reaction mixture ratio weight-to-weight. This precipitate was centrifuged at 3000 rpm for 10 minutes. The resulting supernatant was decanted and discarded. The solids were then placed in a vacuum oven to dry overnight. The dried solids were redispersed into a solvent or a monomer and optionally filtered through a 0.45 micron and then a 0.2-micron PTFE filter.

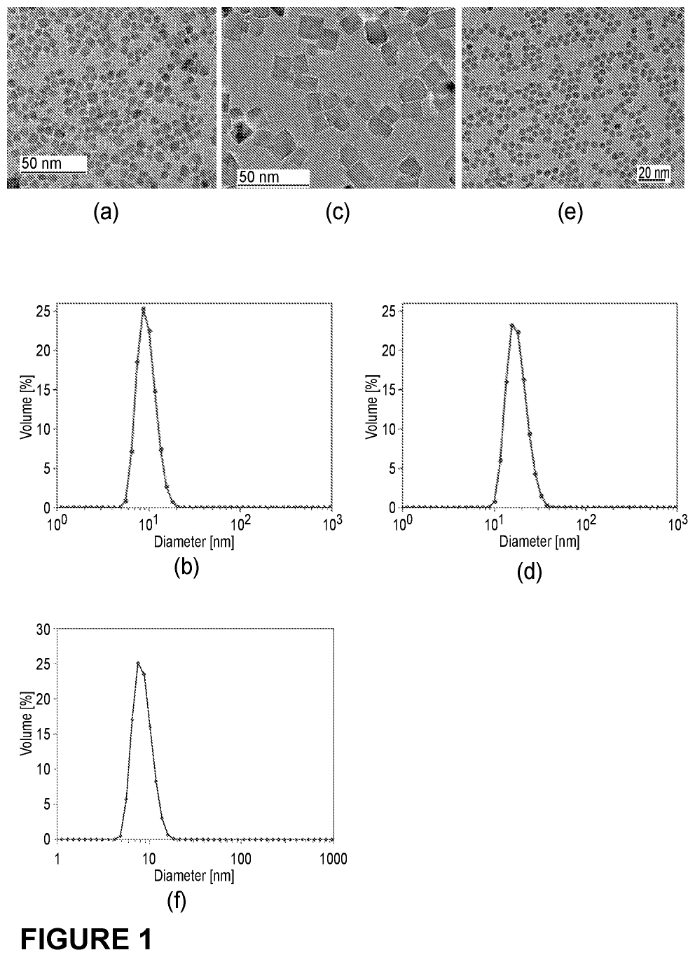

Dispersion properties of exemplary TiO₂ and ZrO₂ nanocrystals are described in FIG. 1. TiO2 nanocrystals with an average core size of 5 nm, as shown in Transmission Electron Microscopy (TEM) image in FIG. 1a, are surface modified or capped with capping agents that make these nanocrystals compatible with various monomers and polymers, including acrylates, epoxies, and siloxanes. The capping agents are designed for maximum compatibility with the polymer matrix. The capped nanocrystals form a uniform dispersion in propylene glycol monomethyl ether acetate (PGMEA) with a single narrow Dynamic Light Scattering (DLS) peak centered around 10 nm (FIG. 1b).

TiO₂ nanocrystals with an average core size of 15 nm as shown in the TEM image in FIG. 1c, are capped with capping agents that make the nanocrystals compatible with many monomers and polymers, including acrylates, epoxies, and siloxanes. These capped nanocrystals also form a uniform dispersion in PGMEA with a single narrow DLS peak centered around 20 nm (FIG. 1d).
ZrO₂ nanocrystals with an average core size of 5 nm, as shown in TEM image (FIG. 1e), are capped with capping agents that make these nanocrystals compatible with various monomers and polymers, including acrylates, epoxies, and siloxanes. These capped nanocrystals also form a uniform dispersion in PGMEA with a single narrow DLS peak centered around 8 nm (Figure if).

### EXAMPLES

In the Examples below, the capped ZrO₂ and/or TiO₂ nanocrystals described above were employed. One of ordinary skill in the art can also use hafnium oxide, zinc oxide, tantalum oxide, niobium oxide, and combinations thereof in addition to or instead of the TiO₂ and ZrO₂ nanocrystals. One of ordinary skill in the would recognize that ZrO₂ and/or TiO₂ nanocrystals with different capping agents could also be used. The examples are illustrative only and do not limit the claimed invention in any way.

### Example 1 (Solvent ZrO₂)

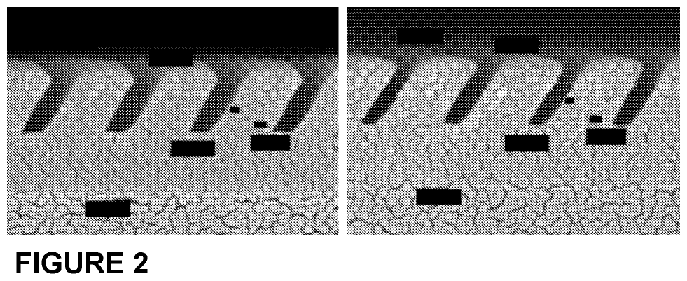

The capped ZrO₂ nanocrystals as described above in “Example Capped ZrO₂ Nanocrystals” were prepared (See Methods of Making A Solvent-free or Solvent-containing Formulation) by incorporating with desired monomers, such as BPMA and PTEA with BMTPS and THEICTA crosslinkers to desired loadings of zirconia in the formulation ranging from 30.6-37.1 wt %, monomer weight percent ranging from 5.9-9.8 wt %, crosslinker weight percent ranging from 2.6-8.5 wt %, and TPO photoinitiator weight percent at 0.5 wt %. Representative formulations of Example 1 are labeled Formulations A1 through A5 according to Table 1 with their viscosity values. Film properties covering clarity, color and film RI (589 nm) with film thicknesses after thermal baking and UV curing steps are displayed for nanocomposites derived from Formulations A1 to A5 in Table 2. These data show transparent films with low haze and film RI values between 1.70-1.80 at 700-830 nm film thicknesses. Because the thermal baking conditions can affect the final film properties, examples A4-1, A4-2, A5-1 and A5-2 are included to show the differences after 2 minutes at 135 C (−1 s) and 200 C (−2 s). FIG. 2 shows the SEM images of formulations A1 and A2 that are nanoimprinted by NIL Technology. FIG. 2 shows nanoimprinted slanted structures with 300 nm features and aspect ratio of 1 (for structure width to slanted structure height).

TABLE 1

| | | | | | | | | | Approximate |
|---|---|---|---|---|---|---|---|---|---|
| | ZrO₂ | BPMA | PTEA | THEICTA | BMTPS | PGMEA | TPO | Viscosity | Solvent-free |
| Formulation | (wt %) | (wt %) | (wt %) | (wt %) | (wt %) | (wt %) | (wt %) | (cP) | Viscosity (cP) |
| A1 | 30.6 | 8.1 | | 7.2 | | 53.7 | 0.5 | 3.8 | 10,000 |
| A2 | 32.4 | 7.1 | | | 6.3 | 53.7 | 0.5 | 3.9 | 4,000 |
| A3 | 34.8 | | 5.9 | | 5.2 | 53.7 | 0.5 | 4.3 | 2,000 |
| A4 | 34.8 | 8.5 | | 2.6 | | 53.7 | 0.5 | 3.4 | |
| A5 | 37.1 | 5.7 | | 3.1 | | 53.7 | 0.5 | 34 | |

TABLE 2

| | | | | | | | | | | | Film | |
|---|---|---|---|---|---|---|---|---|---|---|---|---|
| | ZrO₂ | BPMA | PTEA | THEICTA | BMTPS | | | | | | Thickness | Film RI |
| Nanocomposite | (wt %) | (wt %) | (wt %) | (wt %) | (wt %) | L* | a* | b* | % Haze | YTrans | (um) | (589 nm) |
| A1 | 66.0 | 17.5 | | 15.5 | | 98.77 | 0.72 | 0.47 | 0.31 | 96.86 | 707.1 | 1.711 |
| A2 | 70.0 | 15.4 | | | 13.6 | 98.38 | 0.02 | 0.52 | 0.08 | 95.87 | 811.8 | 1.770 |
| A3 | 75.0 | | 12.7 | | 11.3 | 98.45 | 0.57 | 0.38 | 0.00 | 96.04 | 830.1 | 1.800 |
| A4-1 | 75.0 | 18.3 | | 5.6 | | 98.46 | 0.27 | 0.09 | 0.02 | 96.07 | 898.1 | 1.755 |
| A4-2 | | | | | | 98.38 | −0.40 | 0.46 | 0.03 | 95.85 | 806.7 | 1.773 |
| A5-1 | 80.0 | 14.5 | | 4.4 | | 98.35 | −0.02 | 0.09 | 0.02 | 95.78 | 893.0 | 1.772 |
| A5-2 | | | | | | 98.22 | 0.20 | 0.58 | 0.04 | 95.47 | 809.6 | 1.789 |

### Example 2 (Solvent-Free ZrO₂)

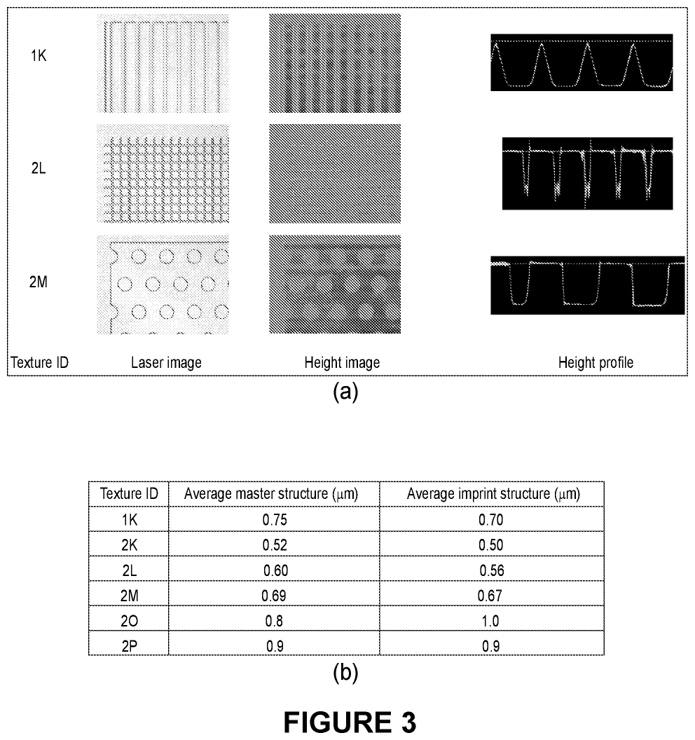

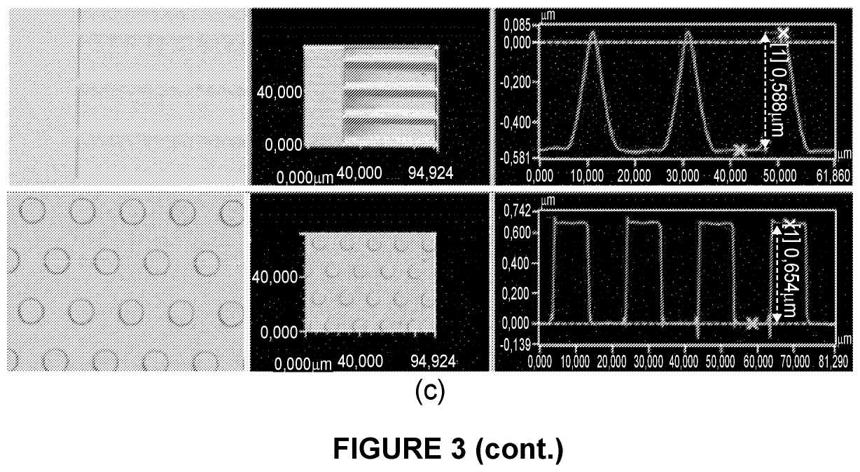

The capped ZrO₂ nanocrystals as described above in “Example Capped ZrO₂ Nanocrystals” were prepared by a solvent extraction process beginning with the ZrO₂ well-dispersed in a low boiling point solvent such as ethyl acetate (ETA) and combined with desired monomers. The monomers include BPMA, PTEA, with BMTPS and THEICTA crosslinkers to desired loadings of zirconia in the formulation ranging from 64.0-70.0 wt %, monomer weight percent ranging from 15.4-26.7 wt %, crosslinker weight percent ranging from 8.2-13.7 wt %, and TPO photoinitiator weight percent at 1.0 wt %. Representative formulations of Example 2 are labeled Formulations B1 and B2 according to Table 3 with their viscosity values. Film properties covering clarity, color and film RI (589 nm) with film thicknesses after UV curing steps are displayed for nanocomposites derived from Formulations B1 to B2 in Table 4. These data show formulations that are nanoimprintable, have low viscosities (<2,000 cP), yield transparent films with low haze and film RI values between 1.70-1.73 at film thicknesses between 6 and 13 microns. FIG. 3 shows the SEM images and corresponding analysis of nanoimprinted structures for formulations B1 and B2 as measured by Morphotonics. The pictures shown in FIG. 3a are triangular, rectangular, and cylindrical gratings of B1 with roughly 700, 560 and 670-nm heights, respectively. Structural fidelity for B1, as depicted by the difference in master and imprint dimensions, are shown in FIG. 3b. FIG. 3c displays similar SEM pictures for B2 with triangular and cylindrical gratings at roughly 600 and 650 nm, respectively.

TABLE 3

| | ZrO₂ | BPMA | PTEA | THEICTA | BMTPS | TPO | Viscosity |
|---|---|---|---|---|---|---|---|
| Formulation | (wt %) | (wt %) | (wt %) | (wt %) | (wt %) | (wt %) | (cP) |
| B1 | 64.0 | 26.7 | | 8.2 | | 1.0 | 1,395 |
| B2 | 70.0 | | 15.4 | | 13.7 | 1.0 | 740 |

TABLE 4

| | | | | | | Film | Film RI |
|---|---|---|---|---|---|---|---|
| Nano- | | | | % | | Thickness | (589 |
| composite | L* | a* | b* | Haze | YTrans | (um) | nm) |
| B1 | 98.85 | −0.06 | 0.41 | 0.07 | 97.04 | 6.38 | 1.696 |
| B2 | 98.64 | 0.00 | 0.39 | 0.11 | 96.53 | 12.87 | 1.730 |

### Example 3 (Solvent TiO₂)

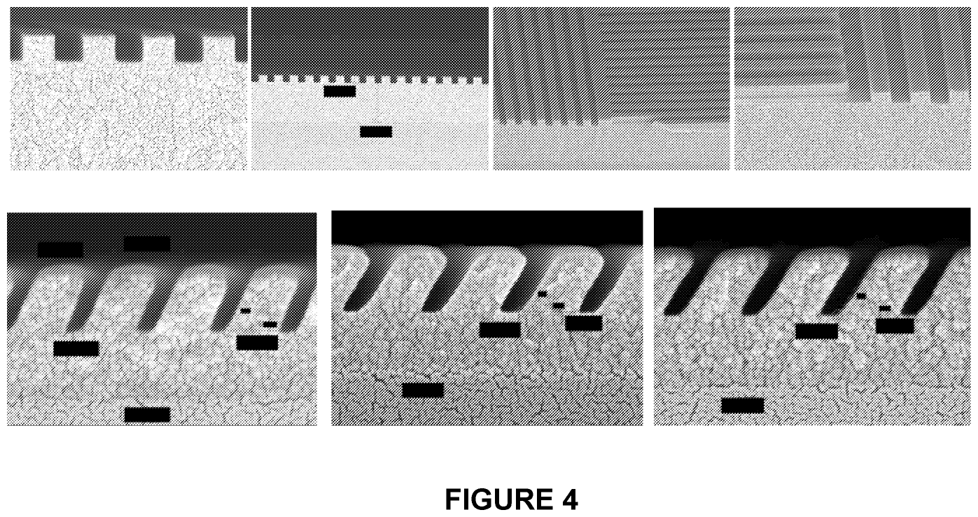

The capped TiO₂ nanocrystals of as described above in “Example Capped TiO₂ Nanocrystals” were prepared by incorporating with desired monomers, such as BPMA, PTEA and PBA with BMTPS, TMPTA, HR6042 and THEICTA crosslinkers to desired loadings of titania in the formulation ranging from 11.6-75.0 wt %, monomer weight percent ranging from 4.2-13.6 wt %, crosslinker weight percent ranging from 2.6-7.2 wt %, and TPO photoinitiator weight percent at 0.5 wt %. Representative formulations of Example 3 are labeled Formulations C1 through C17 according to Tables 5-7 with their viscosity values. Film properties covering clarity, color and film RI (589 nm) with film thicknesses after thermal baking and UV curing steps are displayed for nanocomposites derived from Formulations C1 to C21 in Tables 8-10. These data show transparent films with low haze and film RI values between 1.80-1.91 at 0.66-2.21 microns film thicknesses. Table 11 gives measured nanoindentation data for most of the films. FIG. 4 shows the SEM images of nanoimprints of formulations C1, C2 and C3 as measured by NIL Technology. Binary gratings of C1 are shown in SEM micrographs with structural heights and widths of about 300 and 400 nm, respectively. Additionally, slanted gratings are displayed in FIG. 4 for C1, C2 and C3 with 300 nm features and aspect ratio of 1 (for structure width to slanted structure height).

TABLE 5

| | | | | | | | | | | Approximate |
|---|---|---|---|---|---|---|---|---|---|---|
| | TiO₂ | BPMA | PTEA | PBA | THEICTA | BMTPS | PGMEA | TPO | Viscosity | Solvent-free |
| Formulation | (wt %) | (wt %) | (wt %) | (wt %) | (wt %) | (wt %) | (wt %) | (wt %) | (cP) | Viscosity (cP) |
| C1 | 30.6 | 8.1 | | | 7.2 | | 53.7 | 0.5 | 3.6 | 5,000 |
| C2 | 34.8 | 8.5 | | | 2.6 | | 53.7 | 0.5 | 3.6 | 6,000 |
| C3 | 34.8 | 7.2 | | | 3.9 | | 53.7 | 0.5 | | 8.000 |
| C4 | 32.4 | 7.1 | | | | 6.3 | 53.7 | 0.5 | 5.0 | 3,000 |
| C5 | 33.0 | | 9.8 | | 3.0 | | 53.7 | 0.5 | 2.9 | 250 |
| C6 | 33.0 | | 8.3 | | 4.5 | | 53.7 | 0.5 | | 500 |
| C7 | 34.7 | 3.6 | 3.6 | | 3.9 | | 53.7 | 0.5 | | 6,000 |
| C8 | 34.7 | 4.2 | | 4.2 | 2.6 | | 53.7 | 0.5 | | 7,000 |
| C9 | 28.0 | 6.8 | | 6.8 | 4.2 | | 53.7 | 0.5 | | 400 |
| C10 | 30.0 | | | 12.1 | 3.7 | | 53.7 | 0.5 | 3.2 | 500 |
| C11 | 32.5 | | | 10.2 | 3.1 | | 53.7 | 0.5 | 3.4 | |
| C12 | 37.1 | 5.7 | | | 3.1 | | 53.7 | 0.5 | 3.4 | 10,000 |

TABLE 6

| | 10- | 20- | | | | | | | | |
|---|---|---|---|---|---|---|---|---|---|---|
| | nm | nm | | | | | | | | |
| | TiO2 | TiO₂ | BPMA | THEICTA | BMTPS | TMPTA | HR6042 | PGMEA | TPO | Viscosity |
| Formulation | (wt %) | (wt %) | (wt %) | (wt %) | (wt %) | (wt %) | (wt %) | (wt %) | (wt %) | (cP) |
| C13 | | 34.8 | 6.7 | | | 4.4 | | 53.7 | 0.5 | 3.6 |
| C14 | | 37.0 | 4.4 | | 4.4 | | | 53.7 | 0.5 | 3.6 |
| C15 | | 37.1 | | | | | 8.8 | 53.7 | 0.5 | 3.6 |
| C16 | | 37.1 | 4.4 | | | | 4.4 | 53.7 | 0.5 | 3.6 |
| C17 | 34.8 | | 8.5 | 2.6 | | | | 53.7 | 0.5 | 4.2 |

TABLE 7

| | | | | | | Vis- |
|---|---|---|---|---|---|---|
| Formula- | TiO₂ | BPMA | THEICTA | PGMEA | TPO | cosity |
| tion | (wt %) | (wt %) | (wt %) | (wt %) | (wt %) | (cP) |
| C18 | 11.6 | 2.8 | 0.9 | 84.5 | 0.2 | 1.5 |
| C2 | 34.8 | 8.5 | 2.6 | 53.7 | 0.5 | 3.6 |
| C19 | 52.5 | 12.8 | 3.9 | 30.0 | 0.7 | 16 |
| C20 | 67.5 | 16.5 | 5.1 | 10.0 | 0.9 | 190 |
| C21 | 75.0 | 18.3 | 5.6 | 0.0 | 1.0 | 6,000 |

TABLE 8

| | | | | | | | | | | | | Film | |
|---|---|---|---|---|---|---|---|---|---|---|---|---|---|
| | TiO₂ | BPMA | PTEA | PBA | THEICTA | BMTPS | | | | % | | Thickness | Film RI |
| Nanocomposite | (wt %) | (wt %) | (wt %) | (wt %) | (wt %) | (wt %) | L* | a* | b* | Haze | YTrans | (um) | (589 nm) |
| C1 | 66.0 | 17.5 | | | 15.5 | | 96.60 | −0.88 | 2.15 | 1.39 | 91.47 | 0.820 | 1.837 |
| C2 | 75.0 | 18.3 | | | 5.6 | | 97.26 | −0.18 | 0.94 | 0.34 | 93.08 | 1.026 | 1.911 |
| C3 | 75.0 | 15.5 | | | 8.4 | | 97.57 | 0.23 | 0.73 | 0.11 | 93.84 | 1.145 | 1.874 |
| C4 | 70.0 | 15.4 | | | | 13.6 | 96.76 | 0.43 | 1.99 | 0.77 | 91.86 | 0.923 | 1.916 |
| C5 | 71.3 | | 21.2 | | 6.5 | | 97.41 | 1.53 | 1.07 | 0.00 | 93.41 | 0.660 | 1.885 |
| C6 | 71.3 | | 18.0 | | 9.7 | | 97.44 | −0.08 | 0.92 | 0.00 | 93.53 | 2.14 | 1.847 |
| C7 | 75.0 | 7.8 | 7.8 | | 8.4 | | 97.61 | −0.14 | 0.97 | 0.01 | 93.95 | 2.19 | 1.871 |
| C8 | 75.0 | 9.2 | | 9.2 | 5.6 | | 97.42 | −0.16 | 1.09 | 0.00 | 93.44 | 2.21 | 1.869 |
| C9 | 60.5 | 14.7 | | 14.7 | 9.1 | | 97.85 | −0.13 | 1.17 | 0.63 | 94.53 | 1.24 | 1.796 |
| C10 | 64.8 | | | 26.1 | 8.0 | | 97.97 | −0.26 | 1.15 | 0.05 | 94.84 | 0.809 | 1.811 |
| C11 | 70.2 | | | 22.0 | 6.7 | | 95.74 | 0.53 | −0.18 | 0.06 | 89.38 | 0.793 | 1.850 |
| C12 | 80.0 | 12.3 | | | 6.6 | | 97.40 | 0.58 | 1.01 | 0.00 | 93.42 | 0.796 | 1.904 |

TABLE 9

| | 10- | 20- | | | | | | | | | | | | |
|---|---|---|---|---|---|---|---|---|---|---|---|---|---|---|
| | nm | nm | | | | | | | | | | | Film | |
| | TiO₂ | TiO2 | BPMA | THEICTA | BMTPS | TMPTA | HR6042 | | | | % | | Thickness | Film RI |
| Nanocomposite | (wt %) | (wt %) | (wt %) | (wt %) | (wt %) | (wt %) | (wt %) | L* | a* | b* | Haze | YTrans | (um) | (589 nm) |
| C13 | | 75.0 | 14.4 | | | 9.6 | | 97.88 | 0.63 | 0.78 | 0.03 | 94.61 | 1.875 | 0.767 |
| C14 | | 80.0 | 9.5 | | 9.5 | | | 96.80 | −0.30 | 0.57 | 0.03 | 91.94 | 1.978 | 0.657 |
| C15 | | 80.0 | | | | | 19.0 | 97.10 | −0.10 | 1.19 | 0.00 | 92.68 | | |
| C16 | | 80.0 | 9.5 | | | | 9.5 | 96.99 | −1.66 | 0.62 | 0.09 | 92.43 | 0.685 | 1.967 |
| C17 | 75.0 | | 18.3 | 5.6 | | | | 98.03 | 0.14 | 0.75 | | 94.95 | 0.97 | 1.81 |

TABLE 10

| | | | | | | | | | | Film | |
|---|---|---|---|---|---|---|---|---|---|---|---|
| | TiO2 | BPMA | THEICTA | PGMEA | | | | % | | Thickness | Film RI |
| Nanocomposite | (wt %) | (wt %) | (wt %) | (wt %) | L* | a* | b* | Haze | YTrans | (um) | (589 nm) |
| C18 | 75.0 | 18.3 | 5.6 | 84.5 | 99.63 | 0.18 | 0.03 | 0.13 | 99.04 | 0.101 | 1.903 |
| C2 | | | | 53.7 | | | | | | | |
| C19 | | | | 30.0 | 97.56 | −0.09 | 1.13 | 0.09 | 93.81 | 2.35 | 1.851 |
| C20 | | | | 10.0 | | | 1.56 | 0.21 | | 9.98 | 1.867 |
| C21 | | | | 0.0 | 96.54 | −0.44 | 1.76 | 0.27 | 91.32 | 15.84 | 1.859 |

TABLE 11

| | TiO₂ | BPMA | PTEA | PBA | THEICTA | BMTPS | Hardness | Modulus |
|---|---|---|---|---|---|---|---|---|
| Nanocomposite | (wt %) | (wt %) | (wt %) | (wt %) | (wt %) | (wt %) | (MPa) | (GPa) |
| C2 | 75.0 | 18.3 | | | 5.6 | | 326 | 7.5 |
| C4 | 71.3 | | 21.2 | | 6.5 | | 137 | 4.2 |
| C5 | 71.3 | | 18.0 | | 9.7 | | 334 | 7.6 |
| C6 | 75.0 | 7.8 | 7.8 | | 8.4 | | 374 | 8.6 |
| C7 | 75.0 | 9.2 | | 9.2 | 5.6 | | 349 | 8.6 |
| C8 | 60.5 | 14.7 | | 14.7 | 9.1 | | | |

### Example 4 (Solvent-Free TiO₂)

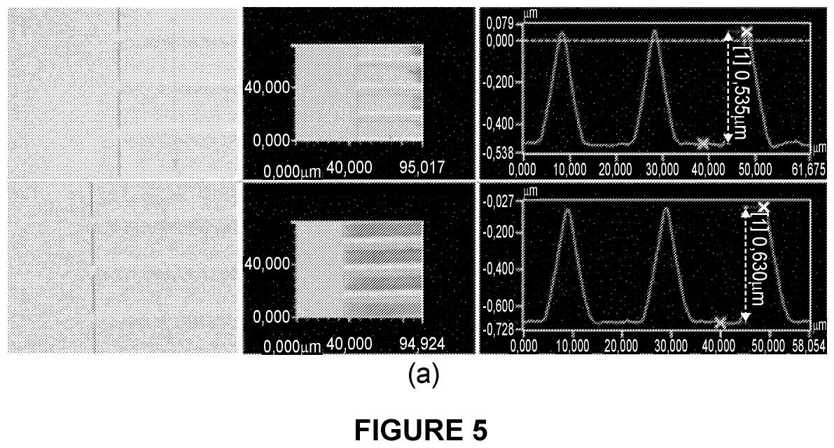

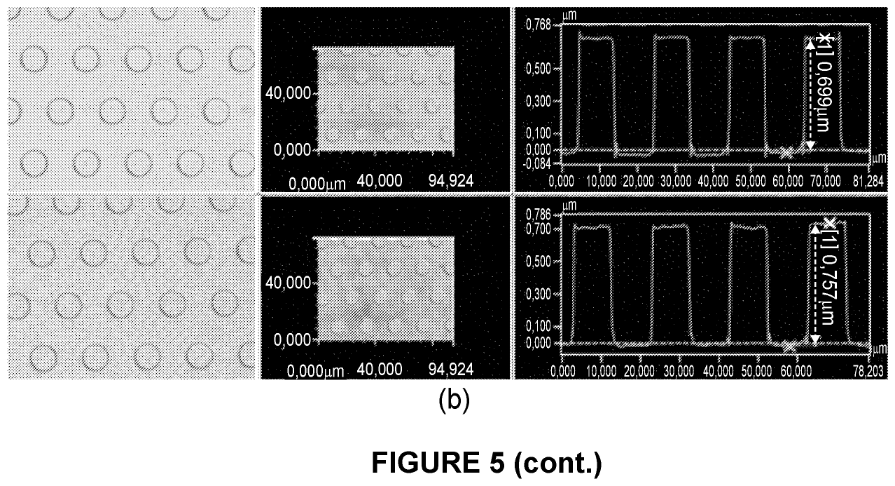

The capped TiO₂ nanocrystals as described above in “Example Capped TiO₂ Nanocrystals” were prepared by a solvent extraction process beginning with the TiO₂ well-dispersed in a low boiling point solvent such as ethyl acetate (ETA) and combined with desired monomers. The monomers include BPMA, PTEA and PBA with THEICTA crosslinker to desired loadings of titania in the formulation ranging from 60.5-73.0 wt %, monomer weight percent ranging from 16.9-29.4 wt %, crosslinker weight percent ranging from 9.1-10.1 wt %, and TPO photoinitiator weight percent at 1.0 wt %. Representative formulations of Example 4 are labeled Formulations D1 to D4 according to Table 12 with their viscosity values. Film properties covering clarity, color and film RI (589 nm) with film thicknesses after thermal baking and UV curing steps are displayed for nanocomposites derived from Formulations D1 to D4 in Table 13. These data show formulations that are nanoimprintable, have low viscosities (≤2,000 cP), yield transparent films with low haze and film RI values between 1.86-1.87 at film thicknesses between 10 and 12 microns. FIG. 5 shows the SEM images and corresponding analysis of nanoimprinted structures for formulations D1 and D2 as measured by Morphotonics. FIGS. 5a and 5b show triangular and cylindrical imprinted structures between 535 and 757 nm (heights) with roughly 300-nm widths.

TABLE 12

| | TiO₂ | BPMA | PTEA | PBA | 2-PEA | THEICTA | TPO | Viscosity |
|---|---|---|---|---|---|---|---|---|
| Formulation | (wt %) | (wt %) | (wt %) | (wt %) | (wt %) | (wt %) | (wt %) | (cP) |
| D1 | 70.0 | | 18.8 | | | 10.1 | 1.0 | 575 |
| D2 | 73.0 | | | | 16.9 | 9.1 | 1.0 | 2,000 |
| D3 | 60.5 | 14.7 | | 14.7 | | 9.1 | 1.0 | 400 |
| D4 | 75.4 | | 15.4 | | | 8.2 | 1.0 | 20,000 |

TABLE 13

| | | | | | | Film | Film RI |
|---|---|---|---|---|---|---|---|
| Nano- | | | | % | | Thickness | (589 |
| composite | L* | a* | b* | Haze | YTrans | (um) | nm) |
| D1 | 97.71 | −0.24 | 1.75 | 0.00 | 94.19 | 11.99 | 1.857 |
| D2 | 97.61 | −0.18 | 1.50 | 0.00 | 93.94 | 10.10 | 1.867 |
| D3 | 97.85 | −0.13 | 1.17 | 0.63 | 94.53 | 1.24 | 1.796 |
| D4 | 95.51 | −0.88 | 1.88 | 0.68 | 88.84 | 22.44 | 1.877 |

### Example 5 (Inkjet-Printable Solvent-Free ZrO₂)

The capped ZrO₂ nanocrystals as described above in “Example Capped ZrO₂ Nanocrystals” were prepared by a solvent extraction process beginning with the ZrO₂ well-dispersed in a low boiling point solvent such as ethyl acetate (ETA) and combined with desired monomers, or the ZrO₂ was well-dispersed directly in desired monomers. The monomers include 2-PEA, BAC, BPMA, HDDA, NVP with THEICTA crosslinker, photoinitiators 1819 and ITX, photo-synergist CN374 and BYK surfactant to desired loadings of zirconia in the formulation ranging from 35-45 wt %, monomer weight percent ranging from 46.0-56.0 wt %, crosslinker weight percent ranging from 0.0-10.0 wt %, and photoinitiator weight percents between 1.0-3.0 wt %, synergist CN374 weight percent at 3.0 wt %. Representative formulations of Example 5 are labeled Formulations E1 to E5 according to Table 14 with their viscosity values. Film properties covering clarity, color and film RI (589 nm) with film thicknesses after UV curing steps are displayed for nanocomposites derived from Formulations E1 to E5 in Table 15. These data show formulations that are inkjet printable at print head temperatures above 30 C, have low viscosities at 25 C (<25 cP), yield transparent films with low haze and film RI values between 1.62 to 1.65 at film thicknesses between 9 and 13 microns.

TABLE 14

| | ZrO₂ | 2-PEA | BAC | BPMA | THEICTA | HDDA | NVP | I819 | ITX | CN374 | BYK | Viscosity |
|---|---|---|---|---|---|---|---|---|---|---|---|---|
| Formulation | (wt %) | (wt %) | (wt %) | (wt %) | (wt %) | (wt %) | (wt %) | (wt %) | (wt %) | (wt %) | (wt %) | (cP) |
| E1 | 40.0 | 28.0 | | 28.0 | | | | 3.0 | | | 1.0 | 24.8 |
| E2 | 40.0 | 32.3 | | 16.2 | 4.0 | 4.0 | | 3.0 | | | 0.5 | 27.0 |
| E3 | 40.0 | 34.5 | | 11.5 | 6.0 | | 4.0 | 3.0 | | | 1.0 | 24.4 |
| E4 | 45.0 | | 32.7 | 16.3 | | | | 1.0 | 1.0 | 3.0 | 1.0 | 21.6 |
| E5 | 45.0 | | 31.3 | 15.7 | 4.0 | | | 1.0 | 1.0 | 1.0 | 1.0 | 22.7 |

TABLE 15

| | | | | | | Film | | |
|---|---|---|---|---|---|---|---|---|
| | | | | | | Thickness | Film RI | Modulus |
| Nanocomposite | L* | a* | b* | % Haze | YTrans | (um) | (589 nm) | (GPa) |
| E1* | 99.41 | −0.10 | 0.31 | 0.00 | 98.49 | 13.0 | 1.639 | 0.69 |
| E2* | 99.31 | −0.14 | 0.46 | 0.06 | 98.23 | 13.0 | 1.624 | 1.08 |
| E3 | 98.89 | −0.18 | 0.61 | 0.00 | 97.44 | 9.1 | 1.632 | 2.24 |
| E4 | 98.90 | −0.11 | 0.45 | 0.07 | 97.19 | 11.2 | 1.638 | 0.72 |
| E5 | 98.90 | 0.04 | 0.71 | 0.02 | 96.93 | 11.8 | 1.640 | 1.30 |

*UV curing performed under N2 atmosphere

### Example 6 (Inkjet-Printable Solvent-Free TiO₂)

The capped TiO₂ nanocrystals as described above in “Example Capped TiO₂ Nanocrystals” were prepared by a solvent extraction process beginning with the TiO₂ well-dispersed in a low boiling point solvent such as ethyl acetate (ETA) and combined with desired monomers, or the TiO₂ was well-dispersed directly in desired monomers. The monomers include 2-PEA, BAC, BPMA, HDDA with THEICTA crosslinker, photoinitiators 1819 and BYK surfactant to desired loadings of titania in the formulation ranging from 40-50 wt %, monomer weight percent ranging from 46.5-56.5 wt %, crosslinker weight of 4.0 wt %, photoinitiator weight percent of 3.0 wt %, and BYK surfactant of 0.5 wt %. Representative formulations of Example 6 are labeled Formulations F1 and F2 according to Table 16 with their viscosity values. Film properties covering clarity, color and film RI (589 nm) with film thicknesses after UV curing steps are displayed for nanocomposites derived from Formulations F1 and F2 in Table 17. These data show formulations that are inkjet printable at print head temperatures above 30 C, have low viscosities at 25 C (≤25 cP), yield transparent films with low haze and film RI values between 1.69 to 1.71 at film thicknesses between 9 and 12 microns.

TABLE 16

| | TiO₂ | 2-PEA | BPMA | THEICTA | HDDA | I819 | BYK | Viscosity |
|---|---|---|---|---|---|---|---|---|
| Formulation | (wt %) | (wt %) | (wt %) | (wt %) | (wt %) | (wt %) | (wt %) | (cP) |
| F1 | 40.0 | 35.0 | 17.5 | 4.0 | | 3.0 | 0.5 | 21.8 |
| F2 | 50.0 | 42.5 | | | 4.0 | 3.0 | 0.5 | 17.9 |

TABLE 17

| | | | | | | Film | Film RI |
|---|---|---|---|---|---|---|---|
| Nano- | | | | % | | Thickness | (589 |
| composite | L* | a* | b* | Haze | YTrans | (um) | nm) |
| F1* | 98.46 | −0.19 | 1.61 | 0.25 | 96.08 | 11.4 | 1.693 |
| F2* | 98.56 | −0.12 | 0.96 | 0.04 | 96.31 | 9.2 | 1.713 |

*UV curing performed under N2 atmosphere

As used herein, the singular form “a”, “an”, and “the”, includes plural references unless it is expressly stated or is unambiguously clear from the context that such is not intended.

The term “and/or” as used in a phrase such as “A and/or B” herein is intended to include both A and B; A or B; A (alone); and B (alone). Likewise, the term “and/or” as used in a phrase such as “A, B, and/or C” is intended to encompass each of the following embodiments: A, B, and C; A, B, or C; A or C; A or B; B or C; A and C; A and B; B and C; A (alone); B (alone); and C (alone).

Headings and subheadings are used for convenience and/or formal compliance only, do not limit the subject technology, and are not referred to in connection with the interpretation of the description of the subject technology. Features described under one heading or one subheading of the subject disclosure may be combined, in various embodiments, with features described under other headings or subheadings. Further it is not necessarily the case that all features under a single heading or a single subheading are used together in embodiments.

The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

With respect to aspects of the invention described as a genus, all individual species are individually considered separate aspects of the invention. If aspects of the invention are described as “comprising” a feature, embodiments also are contemplated “consisting of” or “consisting essentially of” the feature.

The foregoing description of the specific embodiments will so fully reveal the general nature of the invention that others can, by applying knowledge within the ordinary skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the ordinarily skilled artisan in light of the teachings and guidance.

The breadth and scope of the present invention should not be limited by any of the above-described exemplary embodiments.

All of the various aspects, embodiments, and options described herein can be combined in any and all variations.

All publications, patents, and patent applications mentioned in this specification are herein incorporated by reference to the same extent as if each individual publication, patent, or patent application was specifically and individually indicated to be incorporated by reference. To the extent that any meaning or definition of a term in this document conflicts with any meaning or definition of the same term in a document incorporated by reference, the meaning or definition assigned to that term in this document shall govern.

What is claimed is:

1. A formulation comprising at least partially capped metal oxide nanocrystals in a matrix comprising at least one monomer, oligomer or polymer, preferably, the formulation is formulated to be suitable for the preparation of optically clear nanocomposites with % T of >50% and refractive index from 1.6 to 2.1.

2. The formulation of claim 1 wherein the mean particle diameter of the at least partially capped metal oxide nanocrystals is in the range from 1 to 100 nm (such as 1 nm, 5 nm, 10 nm, 15 nm, 20 nm, 30 nm, or any ranges or values between the recited values, e.g., 1-30 nm, 1-20 nm, 5-30 nm, 5-20 nm, etc.), preferably less than 30 nm, as measured by TEM or DLS.

3. The formulation of claim 1 or 2 wherein the metal oxide is selected from zirconium oxide, titanium oxide, hafnium oxide, zinc oxide, tantalum oxide, niobium oxide, and combinations thereof, preferably, the metal oxide is zirconium oxide or titanium oxide.

4. The formulation of any of claims 1 to 3 wherein the at least partially capped metal oxide nanocrystals are capped with at least one capping agent selected from include methyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl], trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, 3-glycidoxypropyltrimethoxysilane, vinyltrimethoxysilane, allyltrimethoxysilane, 1-hexenyltrimethoxysilane, 1-octenyltrimethoxysilane, (phenylaminomethyl) methyldimethoxysilane, N-phenylaminopropyltrimethoxysilane, 3-(4-pyridylethyl)thiopropyltrimethoxysilane, N-(3-trimethoxysilylpropyl)pyrrole, 2-(3-trimethoxysilylpropylthio) thiophene, (3-trimethoxysilylpropyl)diethylene triamine, 11-mercaptoundecyltrimethoxysilane, (2-diphenylphosphino) ethyldimethylethoxysilane, 2-(diphenylphosphino) ethyltriethoxysilane, 3-(diphenylphosphino) propyltriethoxysilane, heptanol, hexanol, octanol, benzyl alcohol, phenol, ethanol, propanol, butanol, oleylalcohol, dodecylalcohol, octadecanol, triethylene glycol monomethyl ether, octanoic acid, acetic acid, propionic acid, 2-[2-(2-methoxyethoxy) ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, 2-mercaptoethanol, 2-{2-[2-(2-mercaptoethoxy)ethoxy)ethoxy]ethoxy} ethanol, 2-(2-methoxyethoxy)ethanethiol, 1-octanethiol, sodium 2,3-dimercaptopropanesulfonate monohydrate, sodium dodecyl sulfate, dodecyl phosphonic acid, octylphosphonic acid, (11-mercaptoundecyl)phosphonic acid, (11-(acryloyloxy)undecyl)phosphonic acid, 11-methacryloyloxyundecylphosphonic acid, [2-[2-(2-methoxyethoxy)ethoxy]ethyl]phosphonic acid ethyl ester, and combinations thereof.

5. The formulation of claim 1 wherein the matrix comprises one or more agents independently selected from (1) acrylate and/or methacrylate monomers, such as those having mono-, di-, tri-, tetra- and other multi-functional reactive chemical groups, (2) reactive diluents, and (3) curing agents or polymerization initiators and, the matrix optionally comprises a surfactant and/or a wetting agent.

6. The formulation of claim 5, comprising the at least partially capped metal oxide nanocrystals in an amount ranging from 20 to 80 wt % (e.g., 20%, 30%, 40%, 50%, 60%, 70%, 80%, or any range or value between the recited values, such as 20-60%, 30-70%, etc.) of the formulation.

7. The formulation of claim 5, comprising the at least partially capped metal oxide nanocrystals in an amount ranging from 20 to 80 wt % (e.g., 20%, 30%, 40%, 50%, 60%, 70%, 80%, or any range or value between the recited values, such as 20-60%, 30-70%, etc.) of the total solids of the formulation.

8. The formulation of claim 6 or 7 wherein the matrix is UV-curable and/or thermally curable.

9. The formulation of any one of claims 1 to 8, comprising a monofunctional acrylate and/or methacrylate monomer with high refractive index, such as, benzyl acrylate (BA), benzyl methacrylate (BMA), ethylene glycol phenyl ether acrylate (PEA), ethylene glycol phenyl ether methacrylate (PEMA), 2-hydroxy-3-phenoxypropyl acrylate (HPPA), 2-hydroxy-3-phenoxypropyl methacrylate (HPPMA), 2-phenoxy benzyl acrylate (PBA), biphenyl methacrylate (BPMA), 2-phenylphenol methacrylate (PPMA), isobutyl acrylate (IBA), 2-phenylethyl acrylate (2-PEA), 2-(phenylthio)ethyl acrylate (PTEA), or a combination thereof.

10. The formulation of any one of claims 1 to 9, comprising a di-, tri-, tetra- and/or penta-functional acrylate and/or methacrylate monomer, such as, 1,6-hexanediol diacrylate (HDDA), 1,6-hexanediol di-methacrylate (HDDMA), di(ethyleneglycol) diacrylate (DEGDA), di(ethyleneglycol) di-methacrylate (DEGDMA), ethylene glycol diacrylate, glycerol 1,3-diglycerolate diacrylate, tri(propylene glycol) diacrylate, trimethylolpropane triacrylate (TMPTA), trimethylolpropane tri-methacrylate (TMPTMA), trimethylolpropane ethoxylate triacrylate (EOTMPTA), trimethylolpropane ethoxylate tri-methacrylate (EOTMPTMA), 1,6-hexanediol ethoxylate diacrylate, tris(2-hydroxyethyl)isocyanurate triacrylate, pentaerythritol tetraacrylate (PETA), dipentaerythritol penta-/hexa-acrylate (DPPA/DPHA), or a combination thereof.

11. The formulation of any one of claims 1 to 10, comprising a crosslinker, preferably, a di-, tri-, and/or tetra-functional thiol crosslinker, such as, trimethylolpropane tris(3-mercaptopropionate).

12. The formulation of any one of claims 1 to 11, comprising one or more high-refractive index and/or sulfur-containing monomers and/or resins, preferably, the monomers and/or resins are selected from the compounds having the following structure and derivatives thereof:

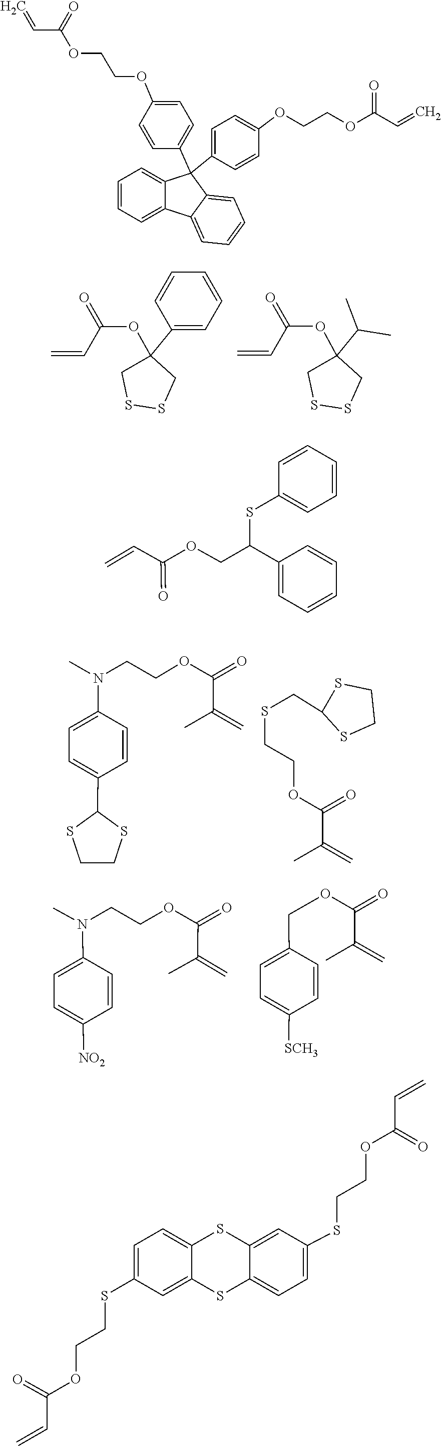

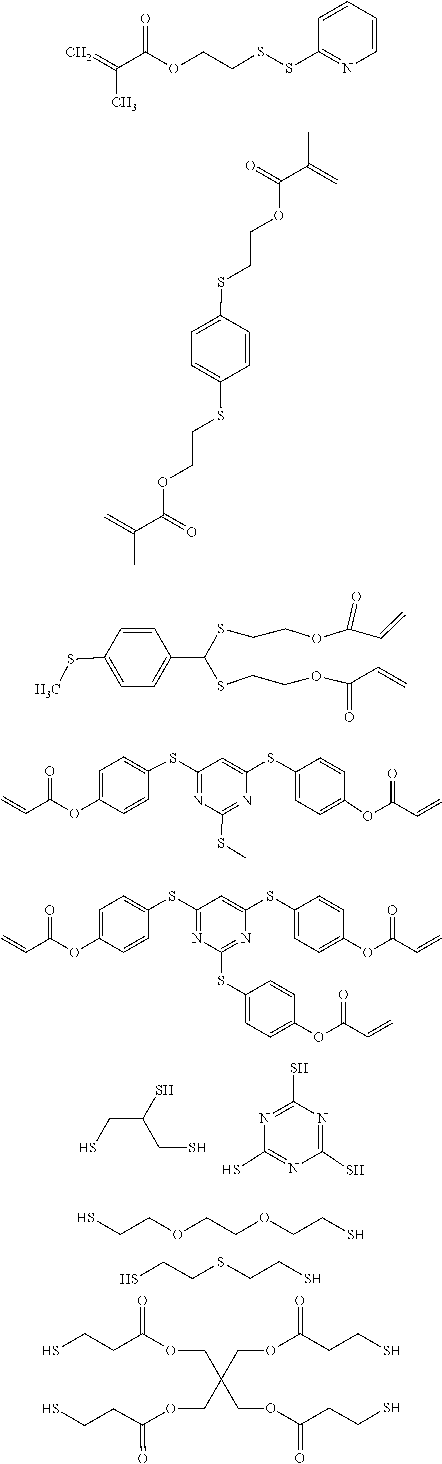

13. The formulation of any one of claims 1 to 12, comprising a reactive diluent, such as, 1-vinyl-2-pyrrolidone (NVP), N-vinyl caprolactam, acrylate morpholine, and 2-carboxyethyl acrylate (2-CEA), wherein the weight percent of the reactive diluent is 0.1-40 wt % with respect to the total formulation, preferrable from 1.0-10 wt %.

14. The formulation of any one of claims 1 to 13, optionally further comprising one or more agents independently selected from a curing agent, a surfactant, a wetting agent, an antioxidant, an adhesion promoter, a leveling agent, a dispersing agent, a plasticizer, a toughener, a thickener, a thinner, a dispersant, a flexibilizer, an organic dopant, and other functional additives wherein the weight percent of the additives range from 0.1-10 wt % with respect to the total formulation.

15. The formulation of any one of claims 1-14 comprising a curing agent or photoinitiator, such as, Irgacure 184, Irgacure 819, TPO, ITX (2-isopropylthioxanthone), Ebercryl P39, with or without a synergist such as Ebercryl P115, CN374, Esacure 1001M, wherein the concentration of said curing agent, photoinitiator and/or synergist within the total formulation is in the range from 0.1-20 wt % (e.g., 0.1%, 1%, 2%, 3%, 5%, 10%, 20%, by weight, or any range or value between the recited values, such as 0.1-5%, 1-10%, etc.) or in the range from 1.0-4.0 wt % (e.g., 1%, 2%, 3%, 4%, by weight, or any range or value between the recited values, such as 2-4%, etc.) with respect to the monomer content.

16. The formulation of any one of claims 1-15, comprising a surfactant and/or wetting agent or a combination of surfactants and/or wetting agents, such as, a polyether-modified siloxane, a fluoro-surfactant, or combinations thereof, that is either non-reactive or reactive in the acrylate monomer system, wherein the concentration of said surfactant and/or wetting agent within the total formulation is in the range from 0.1-2.0 wt % or in the range from 0.5-1.0 wt %.

17. The formulation of any one of claims 1 to 16 wherein the formulation is nanoimprintable to form nanoimprinted structures.

18. The formulation of claim 17 wherein the formulation is nanoimprintable to produce nanoimprinted structures comprising binary, slanted, blazed and other geometries.

19. The formulation of any one of claims 17 to 18 wherein the formulation is nanoimprintable to produce nanoimprinted structures (i.e., height, width, and pitch) on the order of 10 to 1000 nm.

20. The formulation of any one of claims 17 to 19 wherein the formulation is nanoimprintable to produce nanoimprinted structures having aspect ratios of 0.5:1 to 10:1.

21. The formulation of any one of claims 17 to 20 wherein the nanoimprintable formulation comprises a solvent selected from alcohols, glycols, methyl acetates, ethyl acetates, esters, ketones, glycol ethers, glycol esters, such as propylene glycol monomethyl ether acetate (PGMEA), propylene glycol monomethyl ether (PGME), ethylene glycol monobutyl ether acetate, diethylene glycol monobutyl ether acetate, diethylene glycol butyl ether, diethylene glycol monoethyl ether acetate, dipropylene glycol methyl ether acetate, butoxy ethanol, butoxy propanol, ethoxy ethyl acetate, butoxy ethyl acetate, 2-(isopentyloxy)ethanol, 2-(hexyloxy)ethanol, diethylene glycol, diethylene glycol monomethyl ether, diethylene glycol monoethyl ether, triethylene glycol, triethylene glycol monomethyl ether, dipropylene glycol, dipropylene glycol monomethyl ether, and dipropylene glycol monoethyl ether, ethyl acetate, THF, acetone, and any combination thereof.

22. The formulation of any one of claims 17 to 20 comprising a solvent of propylene glycol monomethyl ether acetate (PGMEA) and/or dipropylene glycol methyl ether (DPGME).

23. The formulation of either of claims 21 and 22 wherein the solvent content is between 5 and 10% by weight of the formulation.

24. The formulation of either of claims 21 and 22 wherein the solvent content is greater than 10% by weight of the formulation.

25. The formulation of any one of claims 17 to 24, comprising the at least partially capped metal oxide nanocrystals in an amount selected from 35-40%, 40-45%, 45-50%, 50-55%, 55-60%, 60-65%, 65-70%, 70-75% and 75-80% by weight of the formulation.

26. The formulation of any one of claims 17 to 25, wherein the viscosity of the formulation is within the range of 1-1000 cP when measured at 25° C. with a Brookfield RVDV 11+ cone and plate viscometer, preferred nanoimprintable viscosities are 5-100 cP (e.g., 5 cP, 10 cP, 20 cP, 50 cP, 100 cP, or any range or value in between the recited values, such as 5-50 cP or 5-20 cP, etc.), which are preferable for depositing films with thicknesses ranging from 100 nm to 20 microns.

27. The formulation of claim 21 or 22 wherein the solvent content in the formulation is less than 5% by weight, or the formulation is solvent-free.

28. The formulation of claim 27 comprising the at least partially capped metal oxide nanocrystals in an amount selected from 35-40%, 40-45%, 45-50%, 50-55%, 55-60%, 60-65%, 65-70%, 70-75% and 75-80% by weight of the formulation.

29. The formulation of claim 27 wherein the viscosity of the formulation is within the range of 100-100,000 cP when measured at 25° C. with a Brookfield RVDV II+ cone and plate viscometer, preferred nanoimprintable viscosities are 300-10,000 cP (e.g., 300 cP, 1,000 cP, 2,000 cP, 5,000 cP, 10,000 cP, or any range or value in between the recited values, such as 300-5,000 cP or 1,000-10,000 cP, etc.), which are preferable for depositing films with thicknesses ranging from 100 nm to 20 microns.

30. The formulation of claim 23 or 24 wherein the viscosity of the formulation is within the range of 1-1000 cP when measured at 25° C. with a Brookfield RVDV II+ cone and plate viscometer, preferred inkjettable viscosities are 5-40 cP (e.g., 5 cP, 10 cP, 20 cP, 30 cP, 40 cP, or any range or value in between the recited values, such as 5-30 cP or 10-40 cP, etc.), with printhead heating to temperatures up to 60° C.

31. The formulation of any one of claims 1 to 30 wherein the formulation is inkjet printable, i.e., droplets of the formulation can be ejected from printhead types, such as Dimatix DMC, Fujifilm SG1024/MA, Konica Minolta KM1024i, with droplet volumes between 6-40 pL at drop velocities from 3-9 m/s.

32. The formulation of claim 31 wherein the resistance to drying at or near to the inkjet printhead nozzle plate is appropriate at printing temperatures ranging from 30-60° C. for a period of time ranging from 0.1 minutes to 24 hours.

33. A nanocomposite produced from the formulation of any of claims 1 to 32.

34. A nanocomposite film prepared from a process comprising applying the formulation of any one of claims 1 to 32 via spin coating, slot-die coating, screen-printing, ink-jet printing, nanoimprinting, photopatterning, 3D printing, dip coating, draw-bar coating, roll-to-roll printing, spray coating, dispensing, volume casting, or any combination thereof, to a surface or substrate, and optionally curing the applied formulation.

35. A nanoimprinted nanocomposite produced from the formulation of any of claims 1 to 32.

36. The nanocomposite of any one of claims 33-35 comprising a nanoimprinted structure having a binary, slanted, blazed and/or other geometries.

37. The nanocomposite of any one of claims 33 to 35 comprising a nanoimprinted structure having a height, width, and/or pitch on the order of 10 to 1000 nm (such as 10-200 nm, 50-500 nm, etc.)

38. The nanocomposite of any one of claims 33-37 comprising a nanoimprinted structure having an aspect ratio of 0.5:1 to 10:1 (such as 2:1, 5:1, 8:1, etc.).

39. The nanocomposite of any one of claims 33 to 38 wherein the nanocomposite is a film with a thickness ranging from 10 nanometers to 100 micrometers (such as 10 nm, 100 nm, 500 nm, 1 micron, 10 microns, 20 microns, 50 microns, 100 microns, or any range or value between the recited values, such as 100 nm to 10 microns, 500 nm to 10 microns, etc.), or from 0.5 to 20 micrometers.

40. The nanocomposite of any one of claims 33 to 39 wherein the formulation is cured or partially cured via UV irradiation under a UV LED source with a wavelength at 365 nm, 385 nm, 395 nm, or 405 nm or via a mercury “D”, “H” and/or “V” lamp(s) at a UV dose ranging from 0.1-10 J/cm², or 0.5-2 J/cm² under air, inert atmosphere, such as nitrogen, and/or under the cover of a nanoimprint stamp.

41. The nanocomposite of any one of claims 33 to 40 wherein the formulation is subjected to prebake and/or postbake conditions with a hotplate or convection oven at temperatures ranging from 25-200 C for thermal exposures ranging from 0.01-3 hours that precede and succeed UV irradiation.

42. The nanocomposite of any one of claims 33 to 41 comprising the at least partially capped metal oxide nanocrystals in an amount selected from 35-40%, 40-45%, 45-50%, 50-55%, 55-60%, 60-65%, 65-70%, 70-75% and 75-80% by weight of the nanocomposite.

43. The nanocomposite of any one of claims 33 to 42 having a refractive index ranging from 1.54-1.56, 1.56-1.58, 1.58-1.60, 1.60-1.62, or 1.62-1.64, 1.64-1.66, or 1.66-1.68, or 1.68-1.70, or 1.70-1.72, or 1.72-1.74, or 1.74-1.76 or 1.76-1.78, or 1.78-1.80, or 1.80-1.82, or 1.82-1.84, or 1.84-1.86, or 1.86-1.88, or 1.88-1.90, 1.90-1.92, or 1.92-1.94, or 1.94-1.96, or 1.96-1.98, or 1.98-2.00, or 2.00-2.02, or 2.02-2.04, or 2.04-2.06, or 2.06-2.08, or 2.08-2.10, or greater than 2.10 at 589 nm.

44. The nanocomposite of any one of claims 33 to 43 wherein the % T of the nanocomposite, cured or partially cured, at thicknesses less than 10 microns is 99%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% in the UVA and near UV spectrum from 300-400 nm, the visible wavelength from 400-700 nm, and/or near IR and IR spectrum from 700-1600 nm.

45. The nanocomposite of any one of claims 33 to 44 characterized by a hardness ranging from 1-400 MPa (e.g., 1 MPa, 10 MPa, 50 MPa, 100 MPa, 200 MPa, 300 MPa, 400 MPa, or any range or value between the recited values, such as 10-300 MPa, 50-200 MPa, etc.), as measured by nanoindentation.

46. The nanocomposite of any one of claims 33 to 45 characterized by a Young's modulus ranging from 0.1 to 10 GPa (e.g., 0.1 GPa, 0.5 GPa, 1 GPa, 2 GPa, 5 GPa, 10 GPa, or any range or value between the recited values, such as 0.5-5 GPa, 1-10 GPa, etc.), as measured by nanoindentation.

47. A device comprising the nanocomposite of any one of claims 33-46.
